(19) United States
(12) Patent Application Publication
(10) Pub. No.: US 2017/0299396 A1
(43) Pub. Date: Oct. 19, 2017

(54) APPARATUS, SYSTEM, AND METHOD FOR REFINING GEOGRAPHICAL LOCATION BASED ON DYNAMIC CHARACTERISTICS OF HELMET

(71) Applicant: JARVISH INC., Taipei City (TW)

(72) Inventor: Younger Liang, Taipei City (TW)

(21) Appl. No.: 15/261,989

(22) Filed: Sep. 11, 2016

(30) Foreign Application Priority Data
Apr. 15, 2016 (TW) 105111781

(51) Int. Cl. G01C 21/30; G01R 33/04; G01C 21/08; G01C 19/5783; A42B 3/04; G01S 19/13

(52) U.S. Cl. CPC G01C 21/30; G01S 19/13; G01R 33/04; A42B 3/042; G01C 19/5783; A42B 3/0453; G01C 21/08

(57) ABSTRACT

An apparatus and a method for refining a geographical location based on dynamic characteristics of a helmet are disclosed. A piece of angular velocity information is sensed through a gyroscope and then compared with a piece of basic angular velocity information to generate a piece of dynamic information of the helmet body. The piece of dynamic information, the piece of location information, and the piece of magnetic flux information are marked on an electronic map to generate a piece of refined geographical location information which is then sent to an output unit to be outputted. Thus, a higher resolution of the current geographical location is obtained.

This application claims the priority benefit of Taiwan patent application number 105111781 filed on Apr. 15, 2016.

### BACKGROUND OF THE INVENTION

### Field of the Invention

The present invention relates to an apparatus and a method for refining a geographical location and, in particular, to an apparatus and a method for refining a geographical location based on dynamic characteristics of a helmet such that the user can obtain a higher resolution of the current geographical location and can recognize his/her facing direction and position relative to neighboring landscapes.

### Description of Prior Art

Due to the recent developments of the satellite navigation system, the geographic information system (GIS), and the electronic map services, it is very popular and common for people to identify their current geographical location through mobile devices or navigation devices.

However, the resolution of the obtained current geographic location identified by the user through the traditional search engine, for example, but not limited to, Google map or a car navigation system, is still not high enough. That is, the current mobile devices or navigation devices can only indicate an approximate location area and cannot indicate a precise geographical location. Consequently, the user even changes the location and the identified current geographical location just changes to another approximate location area. If the user is not familiar with his/her surroundings, his/her facing direction and position relative to neighboring landscapes cannot still be identified precisely. If the user is driving a vehicle, an accident can possibly occur due to the operation of the mobile device or navigation devices. Thus, the identification function provided by the current mobile devices or navigation devices still cannot meet the requirements of the user.

In summary, the prior art suffers from the following disadvantages.
1. The resolution of the obtained current geographical location is low.
2. The user cannot recognize his/her facing direction and position relative to neighboring landscapes.
3. An accident is likely to occur.

### SUMMARY OF THE INVENTION

Thus, to effectively overcome the disadvantages of the above issue, one objective of the present invention is to provide an apparatus, system, and method for refining a geographical location based on dynamic characteristics of a helmet, which uses the dynamic characteristics of a helmet body to refine the identified geographical location to increase the resolution of the identified current geographical location.

Another objective of the present invention is to provide an apparatus, system, and method for refining a geographical location based on dynamic characteristics of a helmet, which allows the user wearing the helmet body to quickly recognize his/her facing direction and position relative to neighboring landscapes.

Yet another objective of the present invention is to provide an apparatus, system, and method for refining a geographical location based on dynamic characteristics of a helmet, which decreases the possibility of an accident when the user is identifying his/her current location.

To achieve the above objectives, the present invention provides an apparatus for refining a geographical location based on dynamic characteristics of a helmet, which comprises a helmet body, a storage unit, a gyroscope, a positioning unit, an electronic compass, and a control unit. The storage unit is disposed on the helmet body and stores a piece of basic angular velocity information. The storage unit has an electronic map module for providing an electronic map having a plurality of pieces of landscape and geographical information. The gyroscope is disposed on the helmet body for generating a piece of angular velocity information. The positioning unit is disposed on the helmet body for generating a piece of location information. The electronic compass is disposed on the helmet body for generating a piece of magnetic flux information. The control unit is disposed on the helmet body and is connected to the storage unit, the gyroscope, the positioning unit, and the electronic compass. The control unit receives the piece of angular velocity information, the piece of location information, and the piece of magnetic flux information. The control unit compares the received piece of angular velocity information with the piece of basic angular velocity information in the storage unit to generate a piece of dynamic information. The control unit marks the piece of dynamic information, the piece of location information, and the piece of magnetic flux information on the electronic map to generate a piece of refined geographical location information sent to an output unit. By means of the design of the present invention, the effect of refining the identified geographical location can be effectively achieved; the resolution of the identified current geographical location can be increased; the user can recognize his/her facing direction and position relative to neighboring landscapes; the possibility of an accident can be decreased when the user is identifying his/her current location.

To achieve the above objectives, the present invention provides a system for refining a geographical location based on dynamic characteristics of a helmet, which comprises a server, a helmet body, a storage unit, a gyroscope, a positioning unit, an electronic compass, a communication unit, and a control unit. The server has an electronic map module for providing an electronic map which has a plurality of pieces of landscape and geographical information. The storage unit is disposed on the helmet body and stores a piece of basic angular velocity information. The gyroscope is disposed on the helmet body for generating a piece of angular velocity information. The positioning unit is disposed on the helmet body for generating a piece of location information. The electronic compass is disposed on the helmet body for generating a piece of magnetic flux information. The communication unit is disposed on the helmet body and connected to the server directly or indirectly. The control unit is disposed on the helmet body and is connected to the storage unit, the gyroscope, the positioning unit, and the electronic compass. The control unit receives the piece of angular velocity information, the piece of location information, and the piece of magnetic flux information. The control unit compares the received angular velocity information with the basic angular velocity information in the storage unit to generate a piece of dynamic information. The control unit downloads the electronic map from the server through the communication unit and marks the piece of dynamic information, the piece of location information, and the piece of magnetic flux information on the electronic map to generate a piece of refined geographical location information sent to an output unit. By means of the design of the present invention, the effect of refining the identified geographical location can be effectively achieved; the resolution of the identified current geographical location can be increased; the user can recognize his/her facing direction and position relative to neighboring landscapes; the possibility of an accident can be decreased when the user is identifying his/her current location.

To achieve the above objectives, the present invention also provides a method for refining a geographical location based on dynamic characteristics of a helmet, which is applied to a helmet body. The method comprises the steps of: (a) receiving a piece of angular velocity information, a piece of location information, and a piece of magnetic flux information generated by a gyroscope, a positioning unit, and an electronic compass, respectively, through a control unit disposed on the helmet body, (b) comparing the received piece of angular velocity information with a piece of basic angular velocity information in a storage unit through the control unit to generate a piece of dynamic information, (c) marking the piece of dynamic information, the piece of location information, and the piece of magnetic flux information on an electronic map through the control unit to generate a piece of refined geographical location information, wherein the electronic map has a plurality of pieces of landscape and geographical information, and (d) sending the piece of refined geographical location information by the control unit to an output unit. By means of the design of the present invention, the effect of refining the identified geographical location can be effectively achieved; the resolution of the identified current geographical location can be increased; the user can recognize his/her facing direction and position relative to neighboring landscapes; the possibility of an accident can be decreased when the user is identifying his/her current location.

In an embodiment, the control unit has a dynamic information module and a location refining module. The dynamic information module compares the received piece of angular velocity information with the piece of basic angular velocity information to generate the piece of dynamic information. The location refining module marks the piece of dynamic information, the piece of location information, and the piece of magnetic flux information on the electronic map to generate the piece of refined geographical location information.

In an embodiment, the output unit is selected to be one of a projector, a display, and a speaker.

In an embodiment, the apparatus of the present invention further comprises an input unit disposed on the helmet body and connected to the control unit for generating a command signal sent to the control unit. The control unit controls the gyroscope, the positioning unit, and the electronic compass based on the command signal to generate the piece of angular velocity information, the piece of location information, and the piece of magnetic flux information, respectively.

In an embodiment, the apparatus of the present invention further comprises a photographing unit disposed on the helmet body and connected to the control unit for generating a piece of image information sent to the control unit. The storage unit further comprises an indicator image information module providing at least one indicator image feature and an indicator description corresponding to the indicator image feature. The control unit receives the piece of image information. The control unit further comprises an image recognition module which searches the indicator image information module for the indicator image feature identical to the piece of image information and sends the indicator description corresponding to the indicator image feature to the output unit.

In an embodiment, the indicator image feature of the indicator image information module corresponds to one of the pieces of landscape and geographical information of the electronic map. The control unit further comprises a locating module which receives the piece of the location information and searches for the pieces of landscape and geographical information within a preset distance from the helmet body. The image recognition module searches the indicator image information module based on the pieces of landscape and geographical information for the indicator image feature identical to the piece of image information.

In an embodiment, the apparatus of the present invention further comprises an accelerometer disposed on the helmet body and connected to the control unit for generating a piece of acceleration information sent to the control unit. The control unit further comprises a determination module which determines the helmet body moves in a linear manner or a non-linear manner based on the piece of acceleration information, the piece of location information, and the piece of magnetic flux information. The determination module determines the helmet body is in an upright state or a turning state based on the piece of dynamic information.

In an embodiment, the control unit further comprises a compensation module for providing an offset to compensate the piece of dynamic information.

In an embodiment, the method further comprises the step of controlling the gyroscope, the positioning unit, and the electronic compass through the control unit based on a command signal generated by an input unit to generate the piece of angular velocity information, the piece of location information, and the piece of magnetic flux information, respectively, before the step of receiving the piece of angular velocity information, the piece of location information, and the piece of magnetic flux information generated by the gyroscope, the positioning unit, and the electronic compass, respectively, through the control unit disposed on the helmet body.

In an embodiment, the method further comprises the step of recognizing images which comprises the steps of receiving a piece of image information generated by a photographing unit through the control unit, searching the indicator image information module by the control unit through an image recognition module for the indicator image feature identical to the piece of image information, and sending the indicator description of the indicator image feature identical to the piece of image information by the control unit to the output unit to be outputted.

In an embodiment, the method further comprises the step of searching for the pieces of landscape and geographical information within a preset distance from the helmet body by the control unit through a locating module in which the indicator image feature corresponds to one of the pieces of landscape and geographical information, before the step of searching the indicator image information module by the control unit through the image recognition module for the indicator image feature identical to the piece of image information.

In an embodiment, the step of receiving the piece of angular velocity information, the piece of location information, and the piece of magnetic flux information generated by the gyroscope, the positioning unit, and the electronic compass, respectively, through the control unit disposed on the helmet body further comprises the step of receiving a piece of acceleration information generated by an accelerometer through the control unit.

In an embodiment, the step of comparing the received piece of angular velocity information with the piece of basic angular velocity information in the storage unit through the control unit to generate the piece of dynamic information further comprises the steps of determining the helmet body moves in a linear manner or a non-linear manner based on the piece of acceleration information, the piece of location information, and the piece of magnetic flux information by a determination module of the control unit, determining the helmet body is in an upright state or a turning state based on the piece of dynamic information by the determination module of the control unit, and providing an offset through a compensation module by the control unit to compensate the piece of dynamic information when the determination module of the control unit determines the helmet body moves in the linear manner and in the turning state.

### BRIEF DESCRIPTION OF DRAWING

The purpose of the following figures is to make the present invention understood more easily. The figures will be detailed in the specification and constitute part of the practical embodiments. Through the practical embodiments in the specification with reference to the corresponding figures, the practical embodiments and operating theory of the present invention can be specified and explained clearly.

FIG. 1 is a block diagram according to the first embodiment of the present invention;

FIG. 2 is a perspective view of the helmet body in an upright state according to the first embodiment of the present invention;

FIG. 3 is an alternative block diagram according to the first embodiment of the present invention;

FIG. 4 is a flow chart according to the first embodiment of the present invention;

FIG. 5 is a schematic view of a user wearing a helmet body in an upright state of the present invention;

FIG. 6 is a schematic view of the position of the helmet body with respect to neighboring landscapes;

FIG. 7 is a perspective view of the helmet body in a turning state according to the first embodiment of the present invention;

FIG. 8 is a schematic view of a user wearing a helmet body in a turning state of the present invention;

FIG. 9 is a block diagram according to the second embodiment of the present invention;

FIG. 10 is an alternative block diagram according to the second embodiment of the present invention;

FIG. 11 is a flow chart according to the second embodiment of the present invention;

FIG. 12 is a block diagram according to the third embodiment of the present invention;

FIG. 13 is an alternative block diagram according to the third embodiment of the present invention;

FIG. 14 is a block diagram of the indicator image information module according to the third embodiment of the present invention;

FIG. 15 is a flow chart according to the third embodiment of the present invention;

FIG. 16 is a schematic view of image information according to the third embodiment of the present invention;

FIG. 17 is another schematic view of image information according to the third embodiment of the present invention;

FIG. 18 is a block diagram according to the fourth embodiment of the present invention;

FIG. 19 is an alternative block diagram according to the fourth embodiment of the present invention;

FIG. 20 is a schematic view of a preset distance from the helmet body of the present invention;

FIG. 21 is a flow chart according to the fourth embodiment of the present invention;

FIG. 22 is a block diagram according to the fifth embodiment of the present invention;

FIG. 23 is an alternative block diagram according to the fifth embodiment of the present invention;

FIG. 24 is a flow chart according to the fifth embodiment of the present invention; and

FIG. 25 is a perspective view of the helmet body in a non-upright state according to the fifth embodiment of the present invention.

### DETAILED DESCRIPTION OF THE INVENTION

The above objectives of the present invention and the features of structure and function of the present invention are described according to preferred embodiments in accompanying figures.

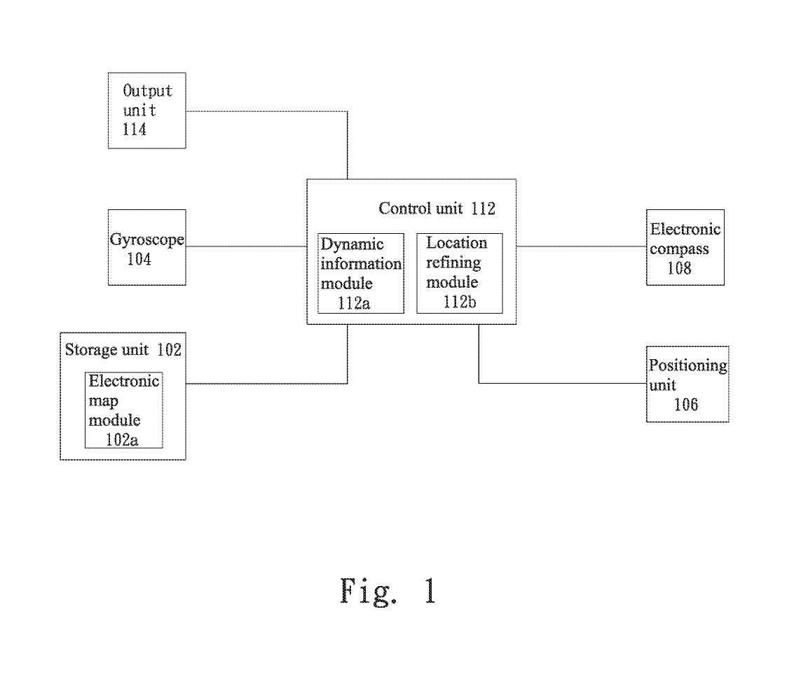

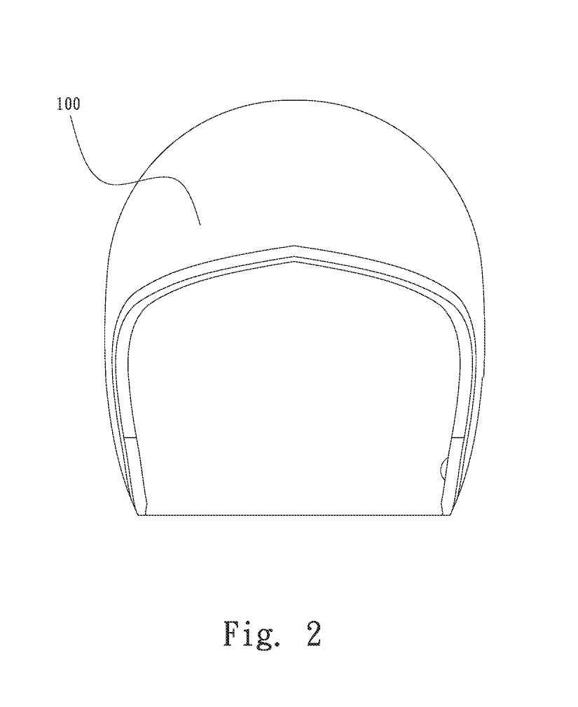

Please refer to FIG. 1, which is a block diagram according to the first embodiment of the present invention. FIG. 2 is a perspective view of the helmet body in an upright state according to the first embodiment of the present invention. The present invention provides an apparatus for refining a geographical location based on dynamic characteristics of a helmet, which comprises a helmet body 100, a storage unit 102, a gyroscope 104, a positioning unit 106, an electronic compass 108, a control unit 112, and an output unit 114. In the current embodiment, a motorcyclist helmet is used as an example of the helmet body 100 for explanation, but not limited to this. In a practical embodiment, the helmet body 100 can be any type of helmet.

The storage unit 102 is disposed on the helmet body 100 and stores a piece of basic angular velocity information as a level value. The piece of basic angular velocity information is the angular velocity of the helmet body 100 in an upright state, as shown in FIG. 2. The storage unit 102 has an electronic map module 102a for providing an electronic map which has a plurality of pieces of landscape and geographical information. The landscape and geographical information includes artificial buildings, streets, road trees, natural objects. In the current embodiment, flash memory is used as an example of the storage unit 102 for explanation, but not limited to this. In a practical embodiment, the storage unit 102 can be made of fixed or mobile RAM (Random Access Memory), ROM (Read Only Memory), or other equivalent devices.

The gyroscope 104 is disposed on the helmet body 100 for generating a piece of angular velocity information based on the turning state of the helmet body 100. In the current embodiment, a three-axis gyroscope is used as an example of the gyroscope 104 for explanation, but not limited to this. In a practical embodiment, the gyroscope 104 can be one of other equivalent devices. The positioning unit 106 is disposed on the helmet body 100 for generating a piece of location information based on the location of the helmet body 100 to identify the location of the helmet body 100 on the electronic map. In the current embodiment, a receiving device of a satellite positioning system such as GPS (Global Positioning System) is used as an example of the positioning unit 106 for explanation, but not limited to this. In a practical embodiment, the positioning unit 106 can be one of other equivalent systems.

The electronic compass 108 is disposed on the helmet body 100 for generating a piece of magnetic flux information to the control unit 112 to identify the reference orientation, for example, east, west, south, and north, of the helmet body 100 with respect to the geographical pole. In the current embodiment, a magnetoresistive sensor is used as an example of the electronic compass 108 for explanation, but not limited to this. In a practical embodiment, the electronic compass 108 can be one of other equivalent magnetic sensors.

The control unit 112 is disposed on the helmet body 100 and is connected to the storage unit 102, the gyroscope 104, the positioning unit 106, and the electronic compass 108. The control unit 112 receives the piece of angular velocity information, the piece of location information, and the piece of magnetic flux information. Then, the control unit 112 controls the dynamic information module 112a to use the piece of basic angular velocity information in the storage unit 102 as a level value which is compared with the received piece of angular velocity information to generate a piece of dynamic information. The control unit 112 marks the piece of dynamic information, the piece of location information, and the piece of magnetic flux information on the electronic map based on the turning state of the helmet body 100 through a location refining module 112b to generate a piece of refined geographical location information which is then sent to an output unit 114.

The control unit 112 can be or can include one or plural programmable general/application-specific microprocessors, Central Processing Unit (CPU), Digital Signal Processor (DSP), Programmable Logic Controller (PLC), Application Specific Integrated Circuit (ASIC), Programmable Logic Device (PLD) and other similar devices or a combination of the above. Also, the output unit 114 has an codec module (not shown) for converting the piece of refined geographical location information to the format which can be outputted by the output unit 114. In the current embodiment, a speaker is used as an example of the output unit 114 for explanation, but not limited to this. In a practical embodiment, the output unit 114 can be a projector, a display or one of other equivalent devices.

In detail, through the change of the angular velocity information of the helmet body 100, the control unit 112 recognizes that the helmet body 100 faces straight ahead (i.e., in the upright state) or turns left, right, up or down (i.e., in the turning state). When the helmet body 100 is in the upright state, the piece of angular velocity information generated by the gyroscope 104 is, for example, zero. Then, the control unit 112 uses the piece of basic angular velocity information in the storage unit 102 as a level value which is compared with the received piece of angular velocity information to generate the piece of dynamic information to identify the helmet body 100 facing straight ahead. When helmet body 100 is in the turning state, the piece of angular velocity information generated by the gyroscope 104 is, for example, non-zero. Then, the control unit 112 recognizes that the helmet body 100 turns left, right, up, or down through the piece of dynamic information and further identifies the helmet body 100 facing left, right, up, or down. After the facing direction of the helmet body 100 is recognized, the control unit 112 marks the facing direction and the piece of location information of the helmet body 100 (i.e., the location of the helmet body 100 shown on the electronic map) and the piece of magnetic flux information (i.e., the reference orientation of the facing direction of the helmet body 100) on the electronic map to further obtain the location and the facing direction with respect to the geographical pole of the helmet body 100, and the partial landscape and geographical information should be obtained when the helmet body 100 is in the facing direction, which are namely the piece of refined geographical location information. The piece of refined geographical location information is then sent to the output unit 114 to be outputted.

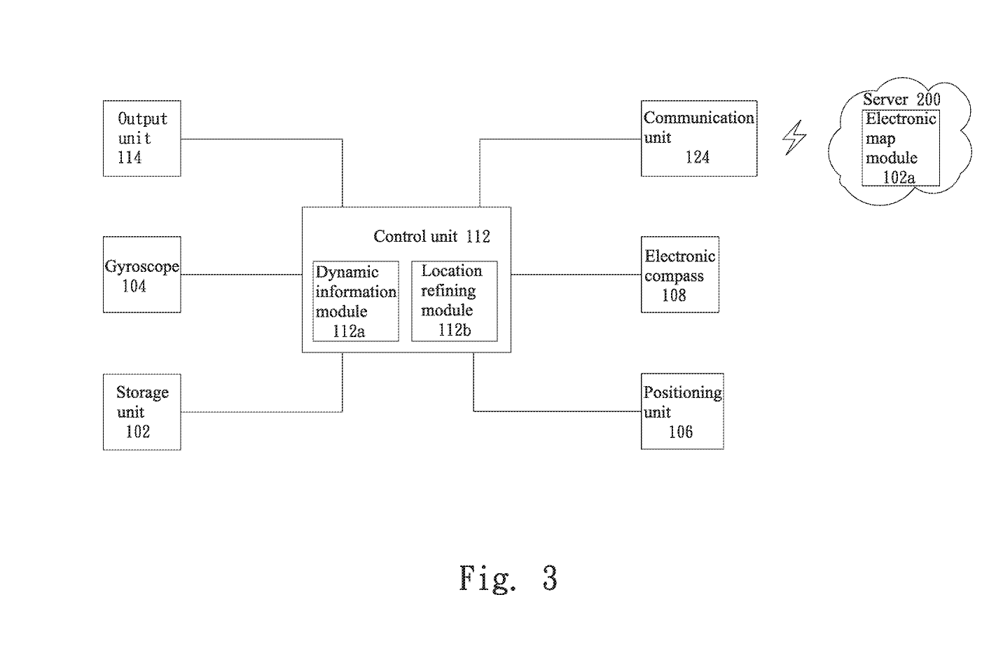

Moreover, in an alternative embodiment based on the first embodiment, referring to FIG. 3 which is an alternative block diagram according to the first embodiment of the present invention, the present invention provides a system for refining a geographical location based on dynamic characteristics of a helmet. The relative relationship among and the functions of the components in the current alternative embodiment are identical to those in the first embodiment and will not be described again. The main difference is that in the current alternative embodiment, the storage unit 102 only stores the piece of basic angular velocity information; the electronic map module 102a is disposed in a server 200; the control unit 112 is connected to the server 200 through a communication unit 124.

The server 200 has an electronic map module 102a and another communication unit (not shown). The electronic map module 102a is used to provide an electronic map which has a plurality of pieces of landscape and geographical information. The landscape and geographical information includes artificial buildings, streets, road trees, natural objects. A 3G device is used as an example of the another communication unit for explanation, but not limited to this. In a practical embodiment, the another communication unit can be a communication device with 4G, LTE, Z-WAVE, ZIGBEE, WIFI, Bluetooth or Infrared, or one of other equivalent communication devices. In the current embodiment, a server host is used as an example of the server 200 for explanation, but not limited to this. In a practical embodiment, the server 200 can be one of other equivalent objects. The communication unit 124 is disposed on the helmet body 100 for connecting the another communication unit such that the control unit 112 is connected to the server 200 directly or indirectly. In the current embodiment, a 3G device is used as an example of the communication unit 124 for explanation, but not limited to this. In a practical embodiment, the communication unit 124 can be a communication device with 4G, LTE, Z-WAVE, ZIGBEE, WIFI, Bluetooth or Infrared, or one of other equivalent communication devices.

The control unit 112 controls the dynamic information module 112a to use the piece of basic angular velocity information in the storage unit 102 as a level value to compare with the received piece of angular velocity information to generate the piece of dynamic information. The control unit 112 downloads the electronic map from the server 200 through the communication unit connected to the another communication unit of the server 200. Then, the control unit 112 marks the piece of dynamic information, the piece of location information, and the piece of magnetic flux information on the electronic map based on the turning state of the helmet body 100 through a location refining module 112b to generate a piece of refined geographical location information which is then sent to an output unit 114.

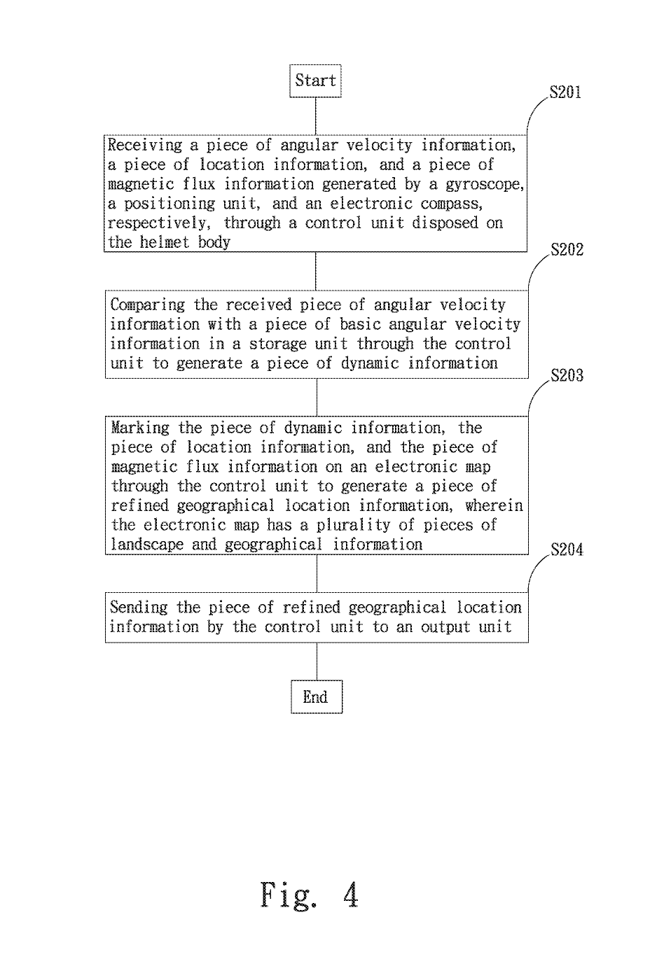

A practical embodiment about the detailed steps of the method for refining a geographical location based on dynamic characteristics of a helmet is given below. Please refer to FIG. 4, which is a flow chart according to the first embodiment of the present invention, accompanying with FIGS. 1-3. The method of the current embodiment is applied to a helmet body 100 of FIG. 2. The following will describe the detailed steps of the method with the components disposed on the helmet body 100.

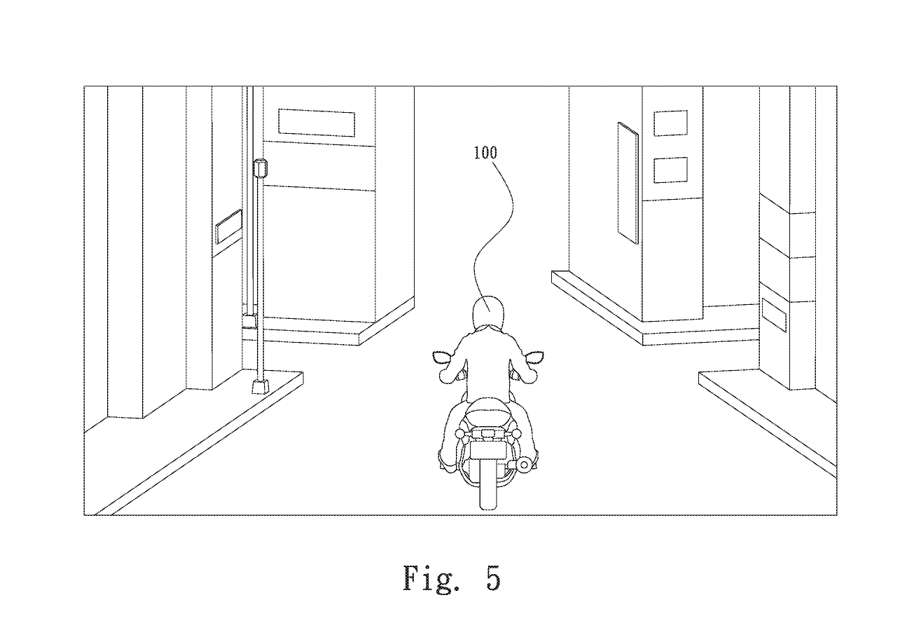

When the user wears and starts to use the helmet body 100 (shown in FIG. 5), first, at step S201, the control unit disposed on the helmet body receives a piece of angular velocity information, a piece of location information, and a piece of magnetic flux information generated by a gyroscope, a positioning unit, and an electronic compass, respectively.

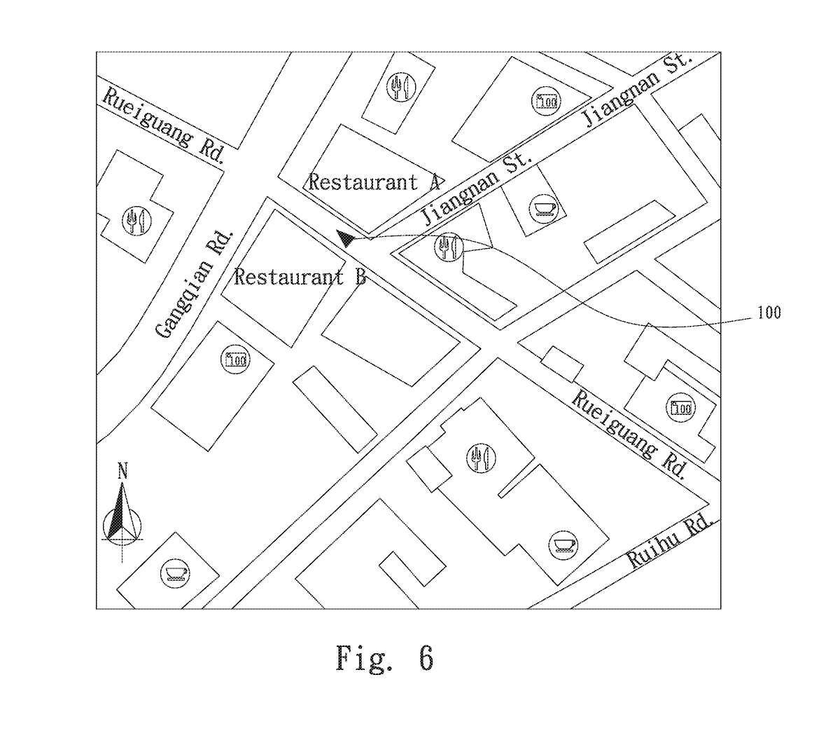

The gyroscope 104 generates the piece of angular velocity information based on the turning direction of the helmet body 100. The positioning unit 106 generates the piece of location information based on the location of the helmet body 100. The electronic compass 108 generates the piece of magnetic flux information based on the reference orientation of the helmet body 100 with respect to the geographical pole. The control unit 112 receives the piece of angular velocity information, the piece of location information, and the piece of magnetic flux information. Please refer to FIG. 6, a solid triangle indicates the geographical location and reference direction of the helmet body 100 in which the piece of location information is, for example, where the solid triangle is located in FIG. 6 and the piece of magnetic flux information is, for example, the directional orientation of the solid triangle in FIG. 6.

Then, at step S202, the control unit compares the received piece of angular velocity information with a piece of basic angular velocity information in a storage unit to generate a piece of dynamic information.

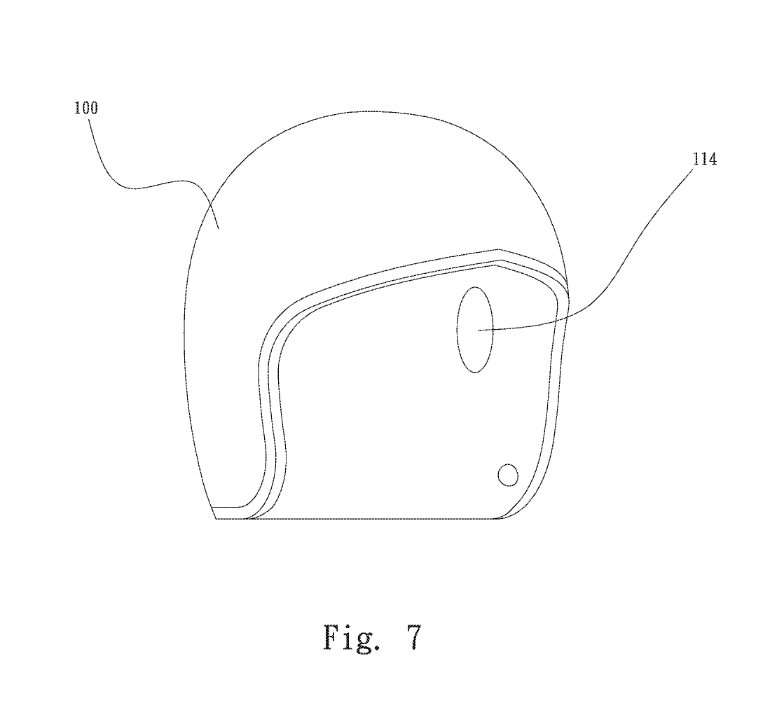

The piece of basic angular velocity information is the angular velocity when the helmet body 100 is in an upright state, as shown in FIG. 2. When the head of the user does not turn and keeps the helmet body 100 in the upright state, the piece of angular velocity information generated by the gyroscope 104 is, for example, zero. Then, the dynamic information module 112a of the control unit 112 uses the piece of basic angular velocity information in the storage unit 102 as a level value to compare with the received piece of angular velocity information to generate the piece of dynamic information and recognizes that the helmet body 100 faces straight ahead. If the head of the user turns and the piece of angular velocity information generated by the gyroscope 104 is not zero, the helmet body 100 is recognized to be in the turning state based on the piece of dynamic information. For example, the helmet body 100 turns left, as shown in FIG. 7.

Next, at step S203, the control unit marks the piece of dynamic information, the piece of location information, and the piece of magnetic flux information on an electronic map to generate a piece of refined geographical location information in which the electronic map has a plurality of pieces of landscape and geographical information.

After the control unit 112 recognizes that the helmet body 100 is in the upright state or the turning state through the change of the angular velocity information of the helmet body 100, the control unit 112 marks the turning direction and the piece of location information of the helmet body 100 (i.e., the location of the helmet body 100 shown on the electronic map) and the piece of magnetic flux information (i.e., the reference orientation) on the electronic map through the location refining module 112b. The electronic map is provided by the electronic map module 102a disposed in the storage unit 102 (shown in FIG. 1) or is provided by the electronic map module 102a disposed in the server 200 (shown in FIG. 3). The control unit 112 downloads the electronic map from the electronic map module 102a of the server 200 through the communication unit 124 connected to another communication unit of the server 200 and performs the marking process to further obtain the location and the facing direction with respect to the geographical pole of the helmet body 100, and the partial landscape and geographical information should be obtained when the helmet body 100 is in the facing direction, which are namely the piece of refined geographical location information.

Finally, at step S204, the control unit sends the piece of refined geographical location information to an output unit.

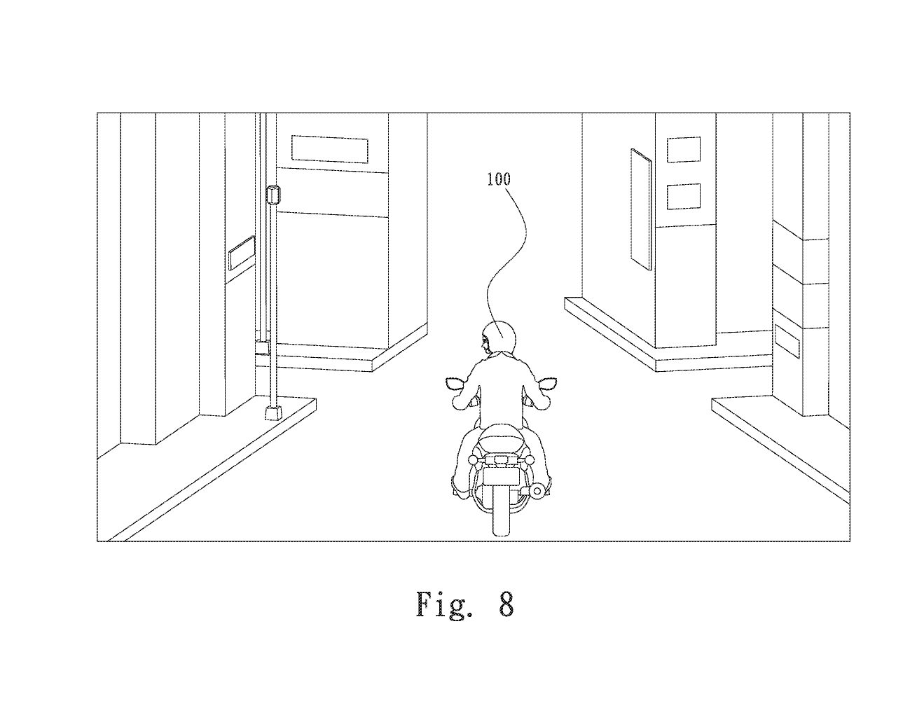

The control unit 112 sends the piece of refined geographical location information to the output unit 114, which is then converted to the format which can be outputted by the output unit 114. For example, when the helmet body 100 is in the upright state, the speaker (i.e., the output unit 114) will say “You are near the intersection of Rueiguang Rd. and Gangqian Rd., Neihu Dist., Taipei City (i.e., the location information). Move ahead (i.e., the dynamic information), Rueiguang Rd, facing the west (i.e., the reference direction). Restaurant A on the right. Restaurant B on the left. Behind is the intersection of Rueiguang Rd. and Jiangnan St. (i.e., the landscape and geographical information of the electronic map),” to inform the user. When the helmet body 100 is in the turning state (shown in FIG. 7), the piece of refined geographical location information indicates the facing direction when the helmet body 100 turns. For example, the head of the user turns left (shown in FIG. 8), the speaker (i.e., the output unit 114) will say “You are near the intersection of Rueiguang Rd. and Gangqian Rd., Neihu Dist., Taipei City (i.e., the location information). Move ahead, Rueiguang Rd, facing the west (i.e., the reference direction). You are facing Restaurant B (i.e., the dynamic information); the address is No. 288, Rueiguang Rd., Neihu Dist., Taipei City (i.e., the landscape and geographical information of the electronic map).” to inform the user.

Compared with the prior art, the piece of refined geographical location information generated through the piece of the dynamic information of the helmet body 100 (i.e., the change of the angular velocity information of the helmet body 100), the piece of location information, and the piece of magnetic flux information marked on the electronic map allows the user to increase the resolution of the identified current geographical location obtained by the user. That is, the user can recognize his/her current location, facing orientation, the facing direction of the user's head, and the position relative to neighboring landscapes, which can decrease the possibility of an accident when the user is identifying his/her current location.

The control unit 112 also can collect, classify, and analyze the pieces of landscape and geographical information of the piece of refined geographical location information outputted by the output unit 114 through the storage unit 102. A value added process can be applied to the pieces of landscape and geographical information such that the possibilities of the pieces of landscape and geographical information shown in the piece of refined geographical location information can be increased or decreased.

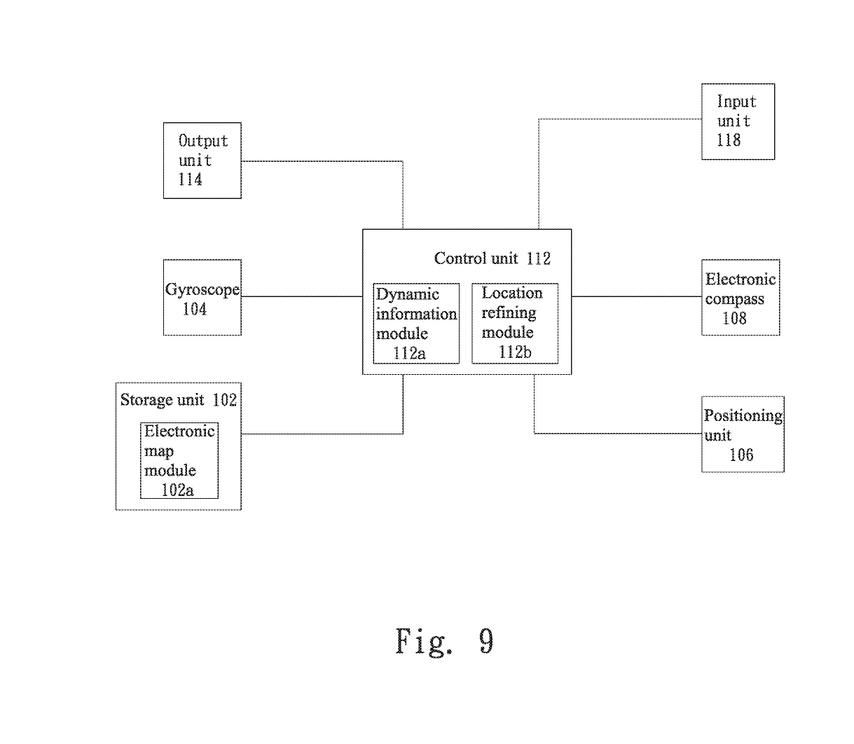

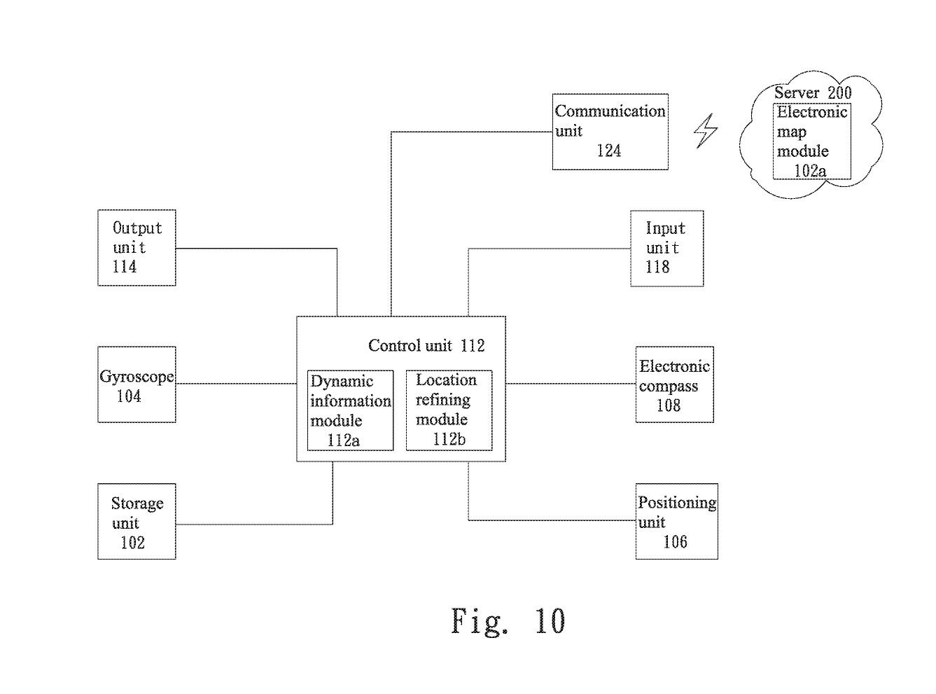

Please refer to FIGS. 9 and 10, which are the block diagram according to the second embodiment of the present invention and the alternative block diagram according to the second embodiment of the present invention, respectively. The relative relationship among and the functions of the components in the current embodiment are identical to those in the first embodiment and the alternative embodiment thereof, and will not be described again. The main difference is that in the second embodiment, the apparatus further comprises an input unit 118 which is disposed on the helmet body 100 and connected to the control unit 112 for generating a command signal sent to the control unit 112. The control unit 112 controls the gyroscope 104, the positioning unit 106, and the electronic compass 108 based on the command signal to generate the piece of angular velocity information, the piece of location information, and the piece of magnetic flux information, respectively. In the current embodiment, a microphone is used as an example of the input unit 118 for explanation, but not limited to this. In a practical embodiment, the input unit 118 can be a touch sensor (for example, but not limited to, capacitive, resistive, or another equivalent touch sensor), a physical button, or another device the command signal can be inputted.

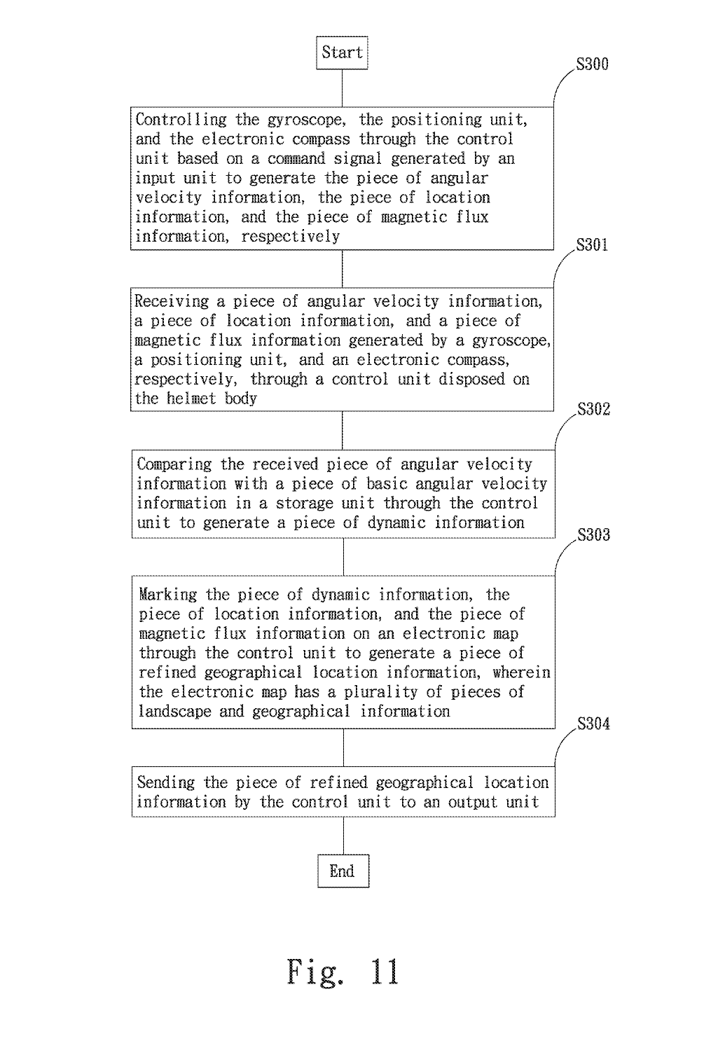

A practical embodiment is given below to describe the detailed steps of the second embodiment and the alternative embodiment thereof. Please refer to FIG. 11, which is a flow chart according to the second embodiment of the present invention accompanying with FIGS. 2, 5, 6, 9, and 10. The following is the detailed description of the steps with the components disposed on the helmet body 100. When the user wears and starts to use the helmet body 100, the user gives an input command (for example, “Where am I?”) to the input unit 118 (i.e., the microphone) by voice.

At step S300, the control unit controls the gyroscope, the positioning unit, and the electronic compass based on a command signal generated by an input unit to generate the piece of angular velocity information, the piece of location information, and the piece of magnetic flux information, respectively.

At the current step, after the control unit 112 receives the command signal generated by the input unit 118, the gyroscope 104, the positioning unit 106, and the electronic compass 108 are actuated (i.e., start to operate) to generate the piece of angular velocity information, the piece of location information, and the piece of magnetic flux information, respectively. After that, steps S301, S302, S303, and S304 are performed in sequence, which are identical to steps S201, S202, S203, and S204, respectively, and not described again. Finally, the piece of refined geographical location information, for example, “You are near the intersection of Rueiguang Rd. and Gangqian Rd., Neihu Dist., Taipei City. Move ahead, Rueiguang Rd, facing the west. Restaurant A on the right. Restaurant B on the left. Behind is the intersection of Rueiguang Rd. and Jiangnan St.”, is outputted by the output unit 114.

Moreover, the user also gives an input command (for example, “What is that?”) to the input unit 118 (i.e., the microphone) by voice. Then, steps S300, S301, S302, S303, and S304 are performed in sequence. Finally, the piece of refined geographical location information, for example, “You are near the intersection of Rueiguang Rd. and Gangqian Rd., Neihu Dist., Taipei City. Move ahead, Rueiguang Rd, facing the west. You are facing Restaurant B; the address is No. 288, Rueiguang Rd., Neihu Dist., Taipei City.”, is outputted by the output unit 114.

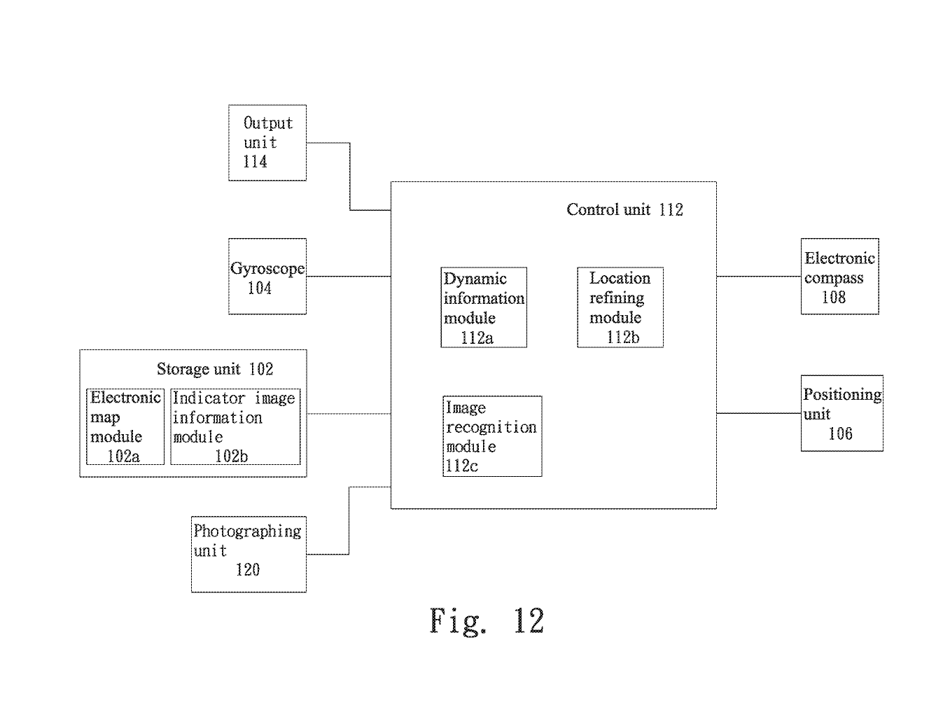

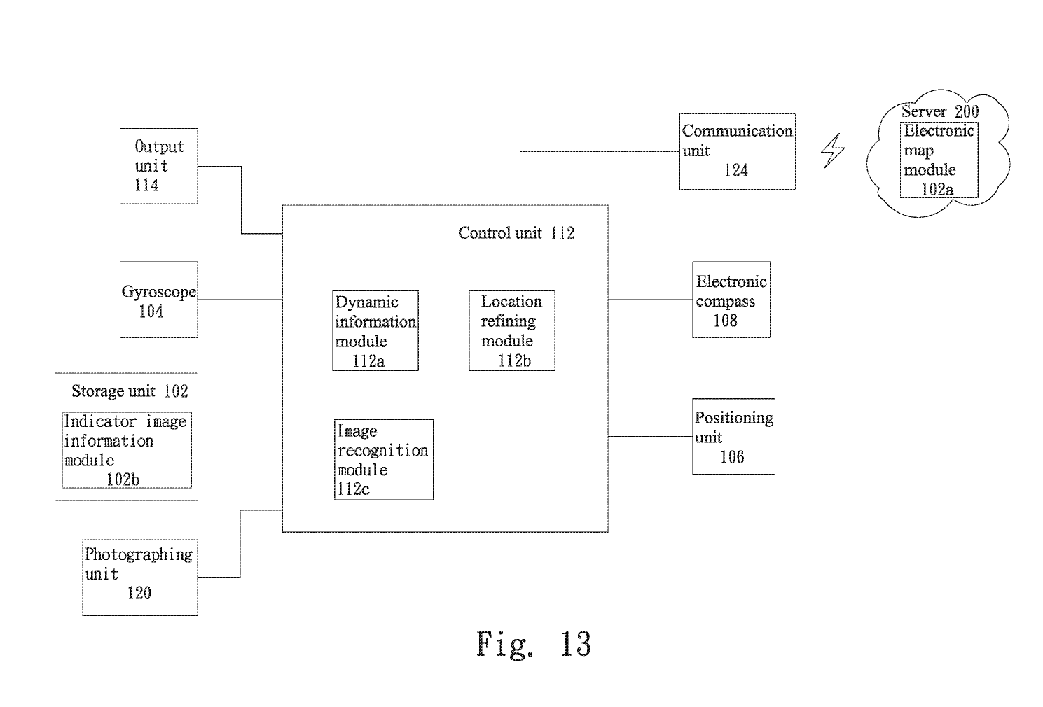

Please refer to FIGS. 12 and 13, which are the block diagram according to the third embodiment of the present invention and the alternative block diagram according to the third embodiment of the present invention, respectively. The relative relationship among and the functions of the components in the current embodiment are identical to those in the first embodiment and the alternative embodiment thereof, and will not be described again. The main difference is that in the third embodiment, the apparatus further comprises a photographing unit 120 disposed on the helmet body 100 and connected to the control unit 112 for generating a piece of image information sent to the control unit 112. In the current embodiment, a camcorder is used as an example of the photographing unit 120 for explanation, but not limited to this. In a practical embodiment, the number of the photographing units 120 is adjustable based on real demand. For example, the number of the photographing units 120 can be two, three, or four.

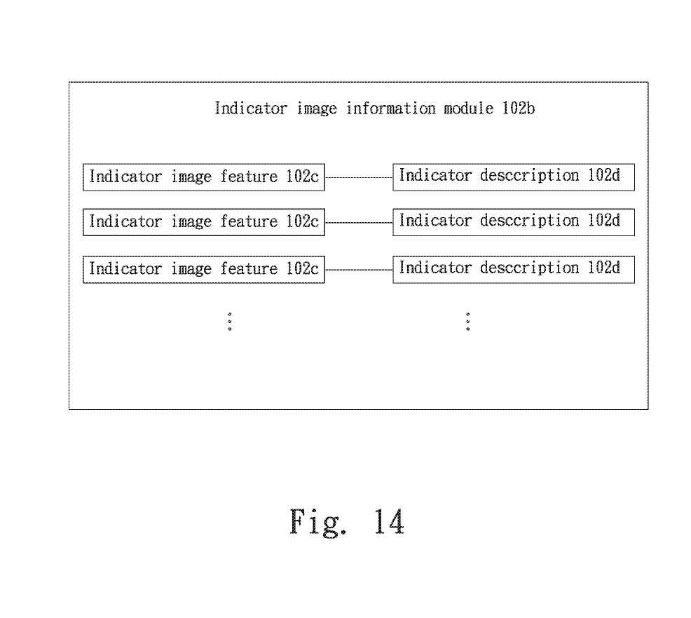

The storage unit 102 further comprises an indicator image information module 102b for providing at least one indicator image feature 102c and an indicator description 102d (shown in FIG. 14) corresponding to the indicator image feature 102c. The indicator image feature 102c is preset to be the image feature on an advertising sign or a signpost. The control unit 112 further comprises an image recognition module 112c which searches the indicator image information module 102b for the indicator image feature 102c identical to the piece of image information. After the indicator image feature 102c identical to the piece of image information is found, the control unit 112 sends the indicator description 102d corresponding to the indicator image feature 102c to the output unit 114. Therefore, compared with the first embodiment and the alternative embodiment thereof, the helmet body 100 in the current embodiment not only can send the piece of refined geographical location information to the output unit 114 to be outputted, but also can send the indicator description 102d corresponding to the indicator image feature 102c to the output unit 114, through the photographing units 120 and the image recognition module 112c of the control unit 112, to inform the user.

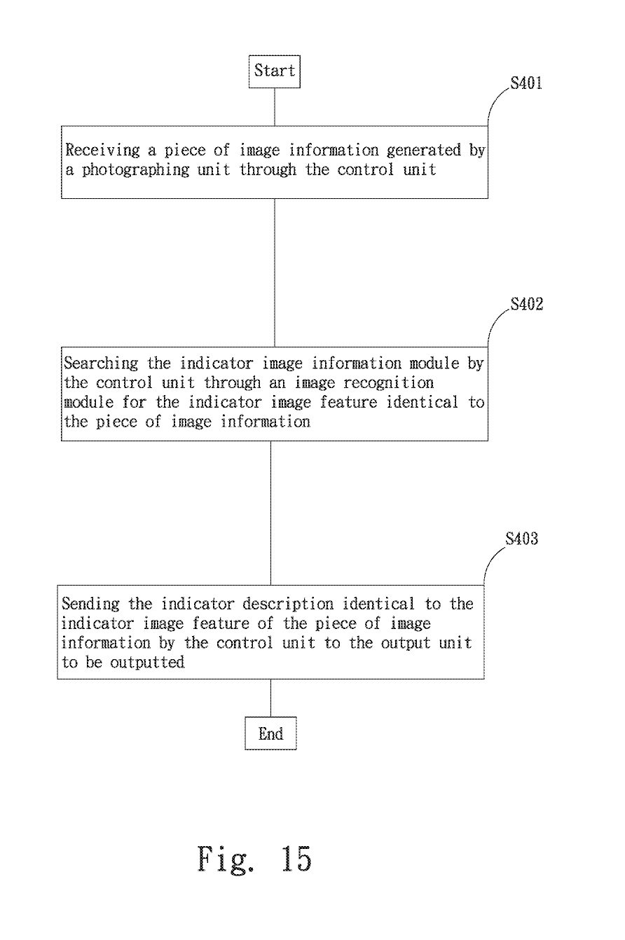

A practical embodiment is given below to describe the detailed steps of the third embodiment and the alternative embodiment thereof. Please refer to FIG. 15, which is a flow chart according to the third embodiment of the present invention accompanying with FIGS. 2, 5, 6, 12, 13, and 14. The following is the detailed description of the steps with the components disposed on the helmet body 100. The method in the current embodiment is an image recognition process applied to the helmet body 100 in FIG. 2 for outputting the indicator information seen by the user. First, at step S401, a piece of image information generated by a photographing unit is received through the control unit.

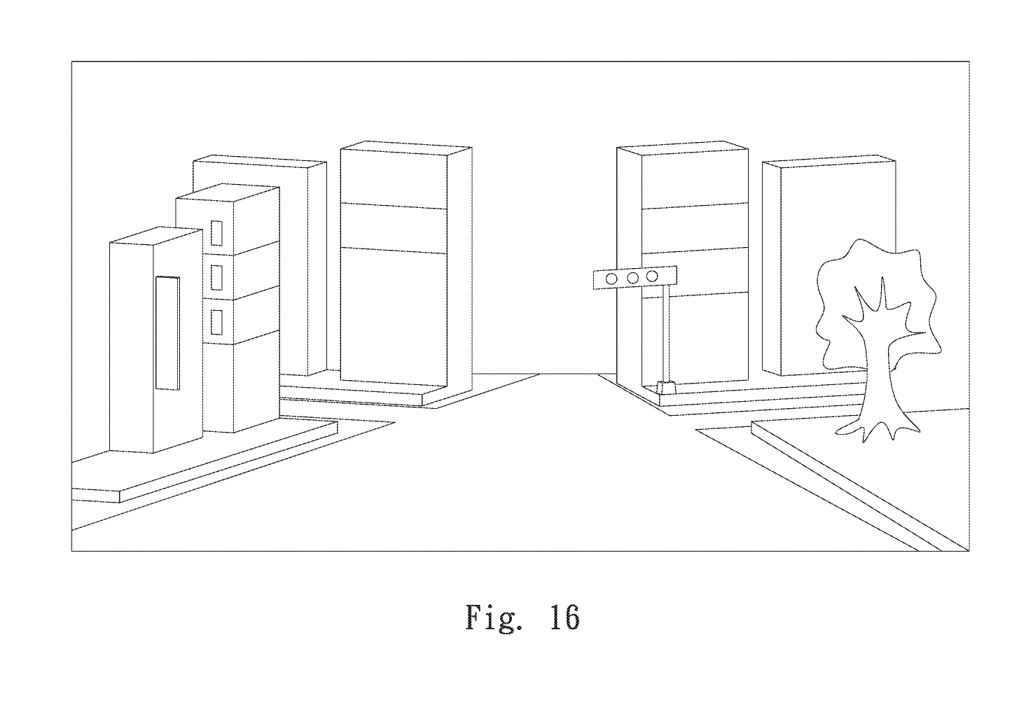

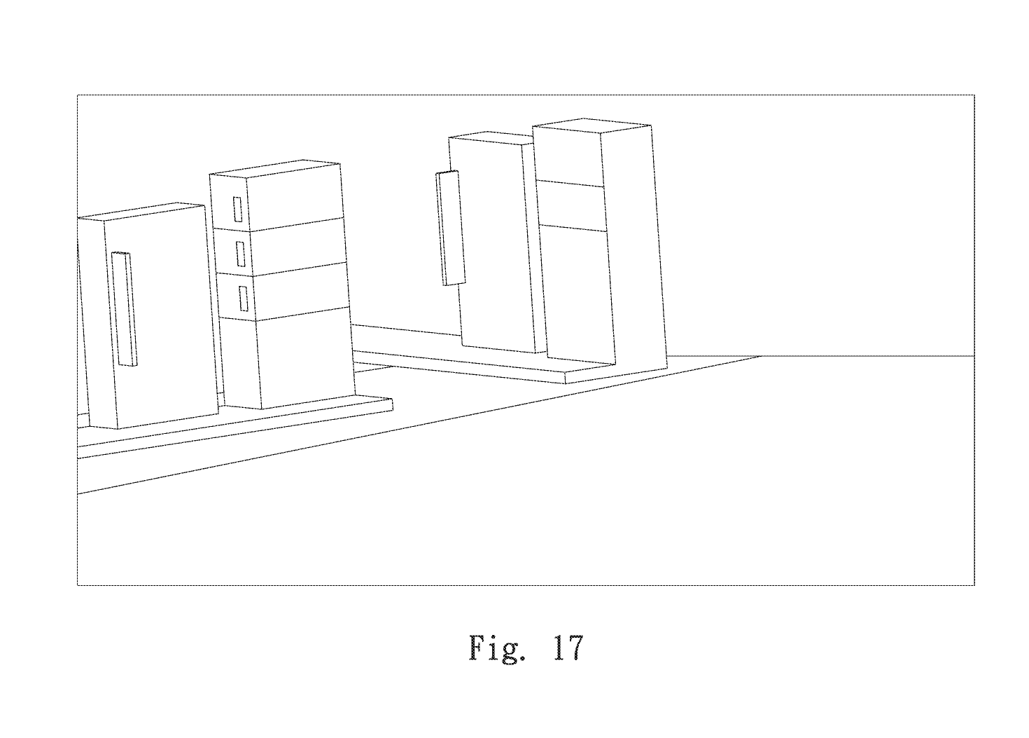

Because the photographing units 120 is disposed on the helmet body 100, it will generate different pieces of image information based on the helmet body 100 being in the upright state or in the turning state, facing up, down, left, or right. For example, when the helmet body 100 is in the upright state, the piece of image information generated by the photographing units 120 is shown, for example, in FIG. 16; when the helmet body 100 is in the turning state (e.g., the head of the user turns left), the piece of image information generated by the photographing units 120 is shown, for example, in FIG. 17 (i.e., the image on the left of the helmet body 100 is shown). Then, the control unit 112 receives the piece of image information.

Next, at step S402, the control unit searches the indicator image information module through an image recognition module for the indicator image feature identical to the piece of image information.

At the current step, the storage unit 102 has the indicator image information module 102b; the control unit 112 has the image recognition module 112c. When the control unit 112 receives the piece of image information generated by the photographing units 120, the control unit 112 searches the indicator image information module 102b through the image recognition module 112c. For example, the piece of image information contains a recognition zone which needs to be recognized and the recognition zone has a piece of recognition information. The piece of image information having an advertising sign is used as an example. The recognition zone is a zone covering the perimeter of the advertising sign; the piece of recognition information is the character shape and color contrast, grayscale, colorfulness, or spectrum in the advertising sign; the indicator image feature 102c has a base point and a standard feature. The image recognition module 112c searches the recognition zone of the piece of image information for the location of the base point corresponding to the indicator image feature 102c. Finally, the piece of recognition information is compared with the standard feature to find the indicator image feature 102c identical to the piece of image information. The above indicator image feature 102c has a corresponding indicator description 102d. For example, the indicator description 102d of an advertising sign is “XXX Cake, 20% Discount for All Items, Telephone No. 02-2796xxxx.” The current step is not limited to use the above-mentioned comparison and recognition to perform image recognition. In a practical embodiment, other equivalent image recognition method also can be used to obtain the effect of the current step.

Next, at step S403, the control unit sends the indicator description identical to the indicator image feature of the piece of image information to the output unit to be outputted.

At the current step, because the indicator image feature has a corresponding indicator description, after the control unit 112 finds the indicator image feature 102c identical to the piece of image information, the control unit 112 sends the indicator description 102d corresponding to the indicator image feature 102c to the output unit 114 to be outputted. That is, the indicator description 102d is sent to the output unit 114 and converted to the format which can be outputted by the output unit 114. For example, the speaker (i.e., the output unit 114) outputs the voice of “XXX Cake, 20% Discount for All Items, Telephone No. 02-2796xxxx.” to inform the user.

Therefore, in the current embodiment, when the user wears the helmet body 100, the present invention not only can send the piece of refined geographical location information, but also can allow the user to obtain the indicator description of the indicator he/she watches through the piece of image information generated by the photographing unit 120 and the image recognition step.

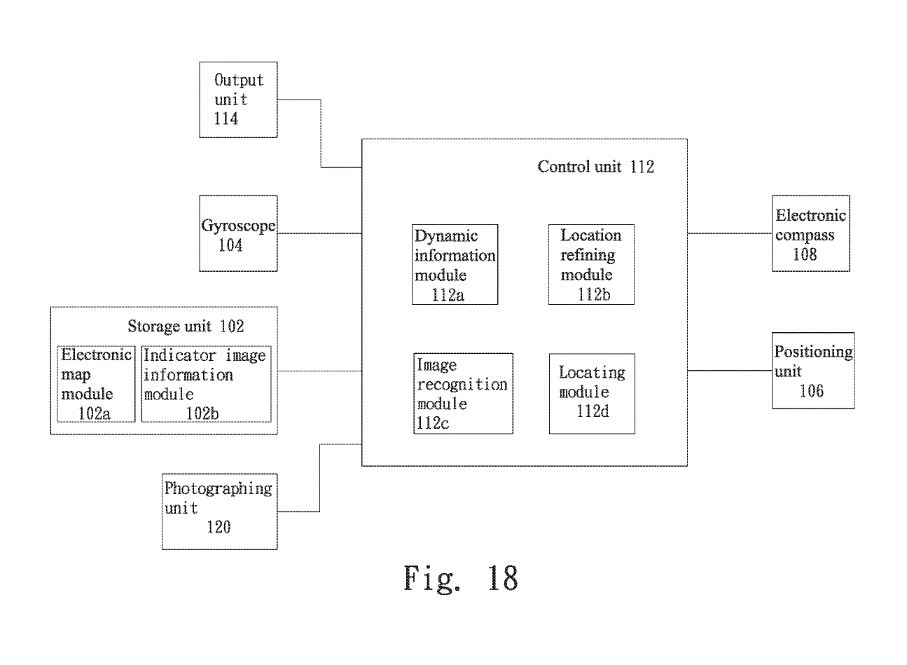

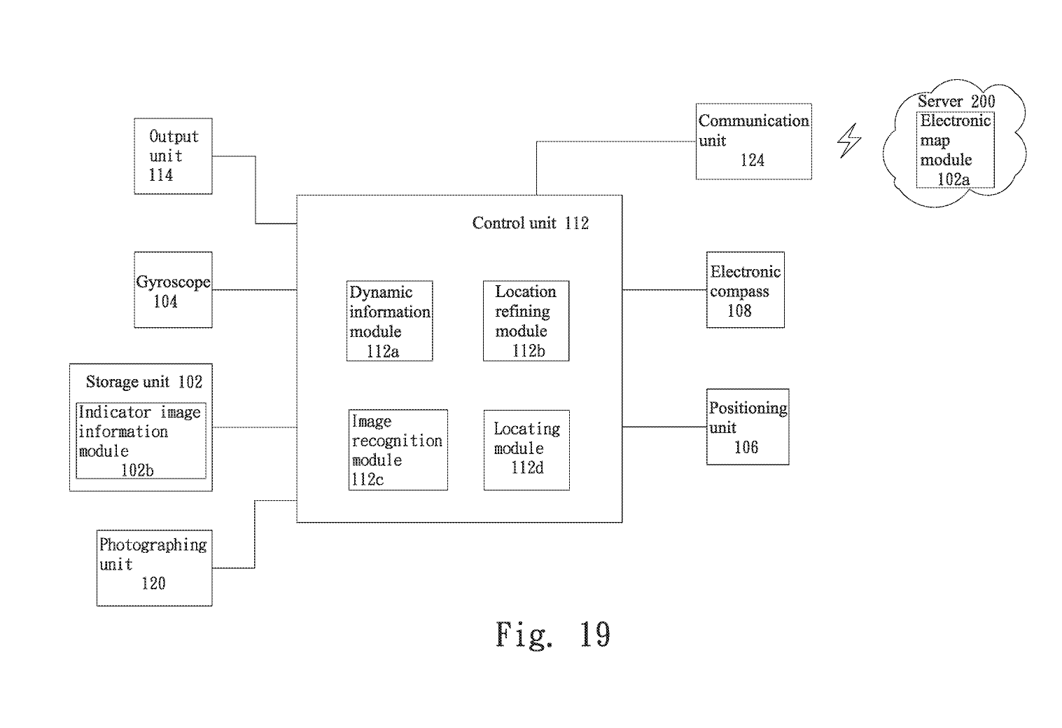

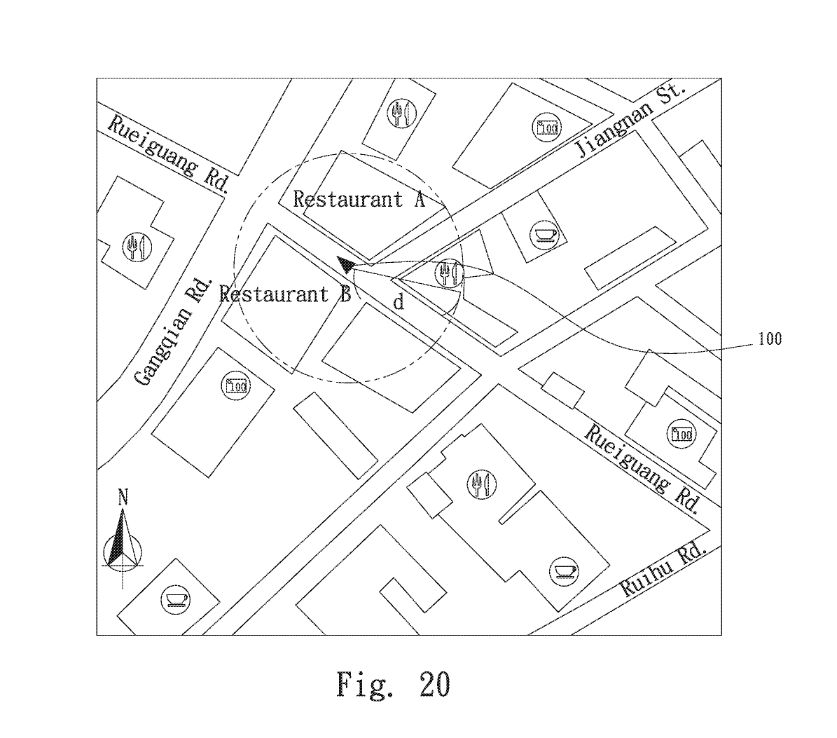

Please refer to FIGS. 18 and 19, which are block diagram according to the fourth embodiment of the present invention and the alternative block diagram according to the fourth embodiment of the present invention, respectively. The relative relationship among and the functions of the components in the current embodiment are identical to those in the third embodiment and the alternative embodiment thereof, and will not be described again. The main difference is that in the fourth embodiment, the indicator image feature 102c of the indicator image information module 102b corresponds to one of the pieces of landscape and geographical information of the electronic map. The control unit 112 further comprises a locating module 112d which searches for the pieces of landscape and geographical information within a preset distance d from the piece of location information (shown in FIG. 20) based on the piece of location information. After the locating module 112d finds the piece of landscape and geographical information, the image recognition module 112c further performs the image recognition through the indicator image information module 102b, which means to search for the indicator image feature 102c identical to the piece of image information.

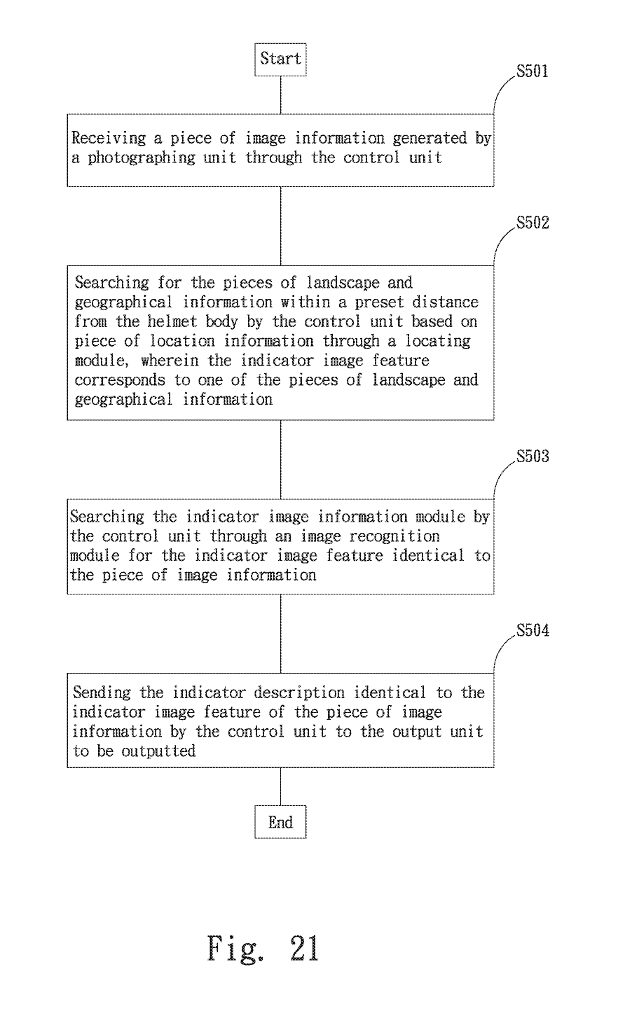

A practical embodiment is given below to describe the detailed steps of the fourth embodiment and the alternative embodiment thereof. Please refer to FIG. 21, which is a flow chart according to the fourth embodiment of the present invention accompanying with FIGS. 5, 6, 18, 19, and 20. The following is the detailed description of the steps with the components disposed on the helmet body 100. Steps S501, S503, S504 in the current embodiment are identical to Steps S401, S402, and S403 in the third embodiment, respectively, and will not be described again.

At step S502, the control unit searches for the pieces of landscape and geographical information within a preset distance from the helmet body based on the piece of location information through a locating module in which the indicator image feature corresponds to one of the pieces of landscape and geographical information.

The control unit 112 identifies the location of the helmet body 100 on the electronic map based on the piece of location information generated by the positioning unit 106. After the control unit 112 receives the piece of image information generated by the photographing units 120, the control unit 112 searches for the pieces of landscape and geographical information within a preset distance from the helmet body 100 on the electronic map, based on the piece of location information through the locating module 112d. For example, in FIG. 20, there are some pieces of landscape and geographical information located within the circle centered at the helmet body 100 having a radius of 500 meters (i.e., the preset distance d). After the locating module 112d searches for all pieces of landscape and geographical information within the circle, the control unit 112 performs step S503. That is, the image recognition module 112c focuses on the indicator image features 102c corresponding to the pieces of landscape and geographical information within the preset distance d through the indicator image information module 102b and performs the image recognition step which is identical to step S402 in the third embodiment and not described again. Finally, the indicator description 102d identical to the indicator image feature 102c of the piece of image information is outputted through the output unit 114 to inform the user (i.e., step S504 which is identical to step S403 in the third embodiment and not described again).

Therefore, in the current embodiment, when the user wears the helmet body 100, the present invention not only can output the piece of refined geographical location information and the indicator description, but also can effectively reduce the time of searching for the indicator image feature 102c identical to the piece of image information by the image recognition module 112c. Further, the user can quickly obtain the indicator description and increase the speed of recognizing his/her position relative to neighboring landscapes and the indicator content.

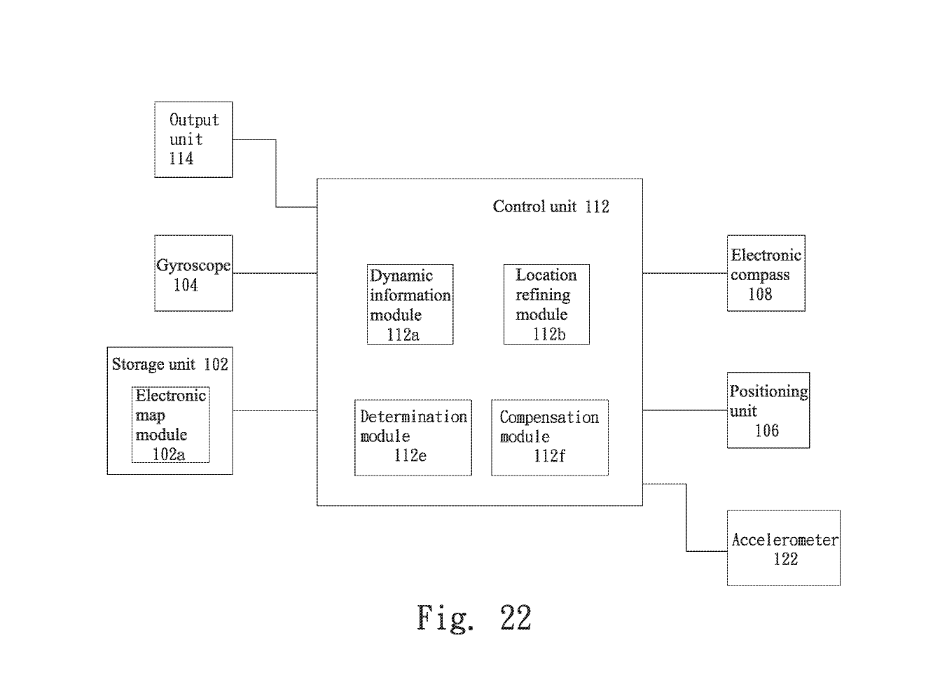

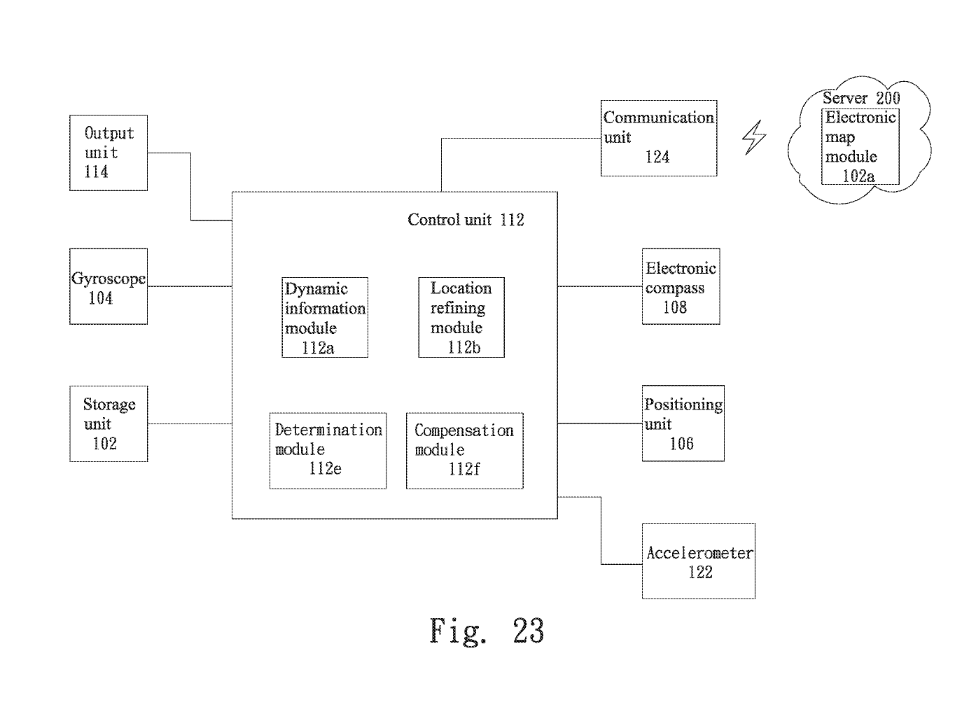

Please refer to FIGS. 22 and 23, which are the block diagram according to the fifth embodiment of the present invention and the alternative block diagram according to the fifth embodiment of the present invention, respectively. The relative relationship among and the functions of the components in the current alternative embodiment are identical to those in the first embodiment and will not be described again. The main difference is that in the current embodiment, the apparatus further comprises an accelerometer 122 disposed on the helmet body 100 and connected to the control unit 112 for generating a piece of acceleration information sent to the control unit 112. The piece of acceleration information is the acceleration of the helmet body 100 in movement. The control unit 112 further comprises a determination module 112e and a compensation module 112f. The determination module 112e determines the helmet body 100 moves in a linear manner or a non-linear manner based on the piece of acceleration information, the piece of location information, and the piece of magnetic flux information. The determination module 112e determines the helmet body 100 is in an upright state or a turning state based on the piece of dynamic information. The compensation module 112f provides an offset to compensate the piece of dynamic information. In the current embodiment, a three-axis accelerometer is used as an example of the accelerometer 122 for explanation, but not limited to this. In a practical embodiment, the accelerometer 122 can be one of other equivalent acceleration-sensing devices.

Therefore, compared with the first embodiment, the helmet body 100 in the current embodiment not only can send the piece of refined geographical location information to the output unit 114 to be outputted, but also can compensate the piece of dynamic information through the accelerometer 122, the determination module 112e of the control unit 112, and the compensation module 112f to output a more precise refined geographical location information.

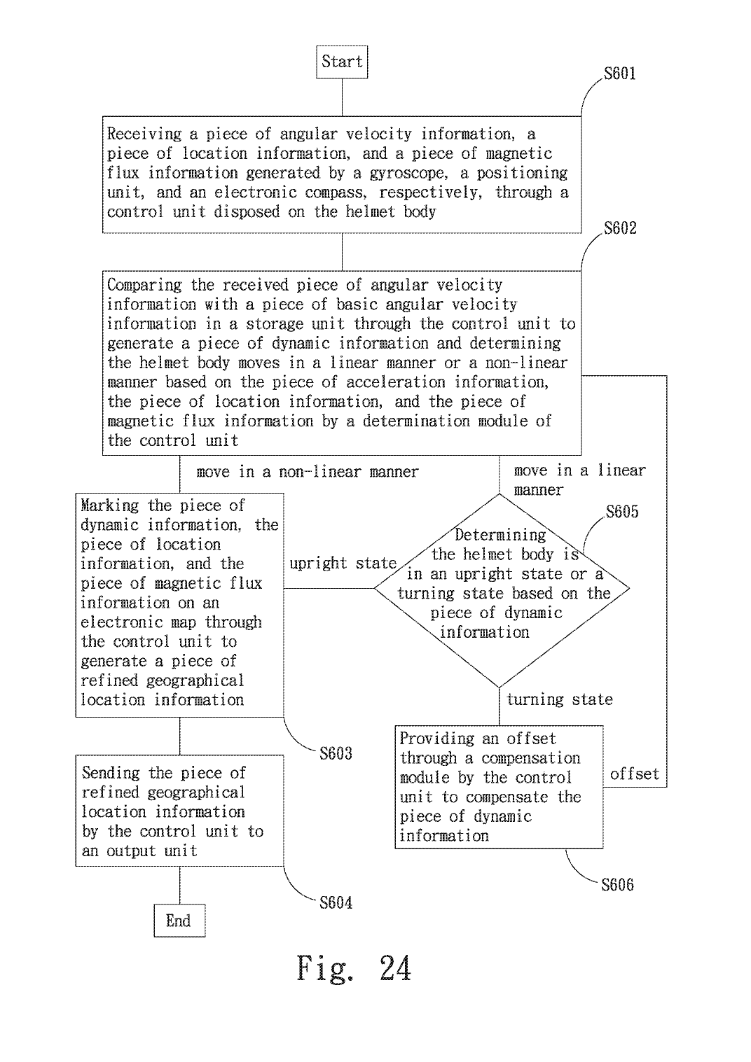

A practical embodiment about the detailed steps of the method for refining a geographical location based on dynamic characteristics of a helmet is given below. Please refer to FIG. 24, which is a flow chart according to the fifth embodiment of the present invention. The method in the current embodiment is a compensation step applied to the helmet body 100 in FIG. 2. Please also refer to FIGS. 2, 4, 5, 6, 7, 22, and 23. The following will describe the detailed steps of the method with the components disposed on the helmet body 100.

At step S601, the control unit disposed on the helmet body receives a piece of angular velocity information, a piece of location information, and a piece of magnetic flux information generated by a gyroscope, a positioning unit, and an electronic compass, respectively.

At the current step, the user wearing the helmet body 100 rides a motorcycle (shown in FIGS. 5 and 6) and the accelerometer 122 disposed on the helmet body 100 generates the piece of acceleration information which is received by the control unit 112. In addition, at the current step similar to step S201 in the first embodiment, the gyroscope 104 generates the piece of angular velocity information based on the turning direction of the helmet body 100. The positioning unit 106 generates the piece of location information based on the location of the helmet body 100. The electronic compass 108 generates the piece of magnetic flux information based on the reference orientation of the helmet body 100 with respect to the geographical pole. The control unit 112 receives the piece of angular velocity information, the piece of location information, and the piece of magnetic flux information.

Next, at step S602, the control unit compares the received piece of angular velocity information with the piece of basic angular velocity information stored in the storage unit to generate the piece of dynamic information and a determination module of the control unit determines the helmet body moves in a linear manner or a non-linear manner based on the piece of acceleration information, the piece of location information, and the piece of magnetic flux information.

At the current step, the determination module 112e of the control unit 112 recognizes the helmet body 100 is moving based on the piece of acceleration information and determines the helmet body 100 moves in a linear manner or a non-linear manner further based on the changes of the piece of location information (i.e., the location of the helmet body 100 should marked on the electronic map) and the piece of magnetic flux information (i.e., the reference orientation). For example, the determination module 112e recognizes that the piece of acceleration information indicates the helmet body 100 moves ahead at a speed of 40 km/hr, the piece of location information indicates each piece of location information of the helmet body 100 at each time moment can form a straight line, and the piece of magnetic flux information indicates there is no change in the reference orientation of the helmet body 100. Consequently, the helmet body 100 is determined to move in a linear manner. Conversely, if the piece of location information indicates each piece of location information of the helmet body 100 at each time moment cannot form a straight line and the piece of magnetic flux information indicates there is some change in the reference orientation of the helmet body 100. Consequently, the helmet body 100 is determined to move in a non-linear manner. The current step is not limited to use the above method to determine the helmet body 100 moves in a linear manner or a non-linear manner. In a practical embodiment, other equivalent determination methods can be used to obtain the effect of the current step.

Next, at step S603, the control unit marks the piece of dynamic information, the piece of location information, and the piece of magnetic flux information on an electronic map to generate a piece of refined geographical location information.

If the determination module 112e of the control unit 112 determines the helmet body 100 moves in a non-linear manner, after the control unit 112 recognizes the helmet body 100 is in the upright state or in the turning state based on the change of the piece of angular velocity information of the helmet body 100, the control unit 112 marks the turning direction and the piece of location information of the helmet body 100 (i.e., the location of the helmet body 100 should marked on the electronic map) and the piece of magnetic flux information of the helmet body 100 (i.e, the reference orientation) on the electronic map through the location refining module 112b. The electronica map can be provided by the electronic map module 102a disposed in the storage unit 102 (shown in FIG. 1) or by the electronic map module 102a disposed in the server 200 (shown in FIG. 3) in which the control unit 112 is connected to another communication unit (not shown) of the server 200 through the communication unit 124 such that the control unit 112 downloads the electronic map from the electronic map module 102a of the server 200 and performs the marking process to further obtain the location and the facing direction with respect to the geographical pole of the helmet body 100, and the partial landscape and geographical information should be obtained when the helmet body 100 is in the facing direction, which are namely the piece of refined geographical location information.

Then, at step S604, the control unit sends the piece of refined geographical location information to an output unit.

The control unit 112 sends the piece of refined geographical location information to the output unit 114, which is then converted to the format which can be outputted by the output unit 114. For example, when the helmet body 100 is in the upright state, the speaker (i.e., the output unit 114) will say “You are near the intersection of Rueiguang Rd. and Gangqian Rd., Neihu Dist., Taipei City (i.e., the location information). Move ahead (i.e., the dynamic information), Rueiguang Rd, facing the west (i.e., the reference direction). Restaurant A on the right. Restaurant B on the left. Behind is the intersection of Rueiguang Rd. and Jiangnan St. (i.e., the landscape and geographical information of the electronic map),” to inform the user. When the helmet body 100 is in the turning state (shown in FIG. 7), the piece of refined geographical location information indicates the facing direction when the helmet body 100 turns. For example, the head of the user turns left (shown in FIG. 8), the speaker (i.e., the output unit 114) will say “You are near the intersection of Rueiguang Rd. and Gangqian Rd., Neihu Dist., Taipei City (i.e., the location information). Move ahead, Rueiguang Rd, facing the west (i.e., the reference direction). You are facing Restaurant B (i.e., the dynamic information); the address is No. 288, Rueiguang Rd., Neihu Dist., Taipei City (i.e., the landscape and geographical information of the electronic map).” to inform the user.

At step S605, the determination module of the control unit determines the helmet body is in an upright state or a turning state based on the piece of dynamic information.

If the determination module 112e of the control unit 112 determines the helmet body 100 moves in a linear manner, the control unit 112 identifies the helmet body 100 is in the upright state or in the turning state based on the change of the piece of angular velocity information of the helmet body 100. Because the piece of basic angular velocity information is the angular velocity of the helmet body 100 in the upright state (shown in FIG. 2), when the head of the user does not turn and the helmet body 100 keeps in the upright state, the piece of angular velocity information generated by the gyroscope 104 is, for example, zero. Then, the dynamic information module 112a of the control unit 112 uses the piece of basic angular velocity information in the storage unit 102 as a level value which is compared with the received piece of angular velocity information to generate the piece of dynamic information to identify the helmet body 100 facing straight ahead. If the head of the user turns and the piece of angular velocity information generated by the gyroscope 104 is not zero, the helmet body 100 is determined to be in in the turning state based on the piece of dynamic information. For example, the helmet body 100 turns left, as shown in FIG. 7.

If the determination module 112e of the control unit 112 determines the helmet body 100 moves in a linear manner and the helmet body 100 is determined to be in the upright state based on the piece of dynamic information, step S603 is performed.

At step S606, if the determination module 112e of the control unit 112 determines the helmet body 100 moves in a linear manner and the helmet body 100 is in the upright state, the control unit 112 provides an offset through a compensation module to compensate the piece of dynamic information.

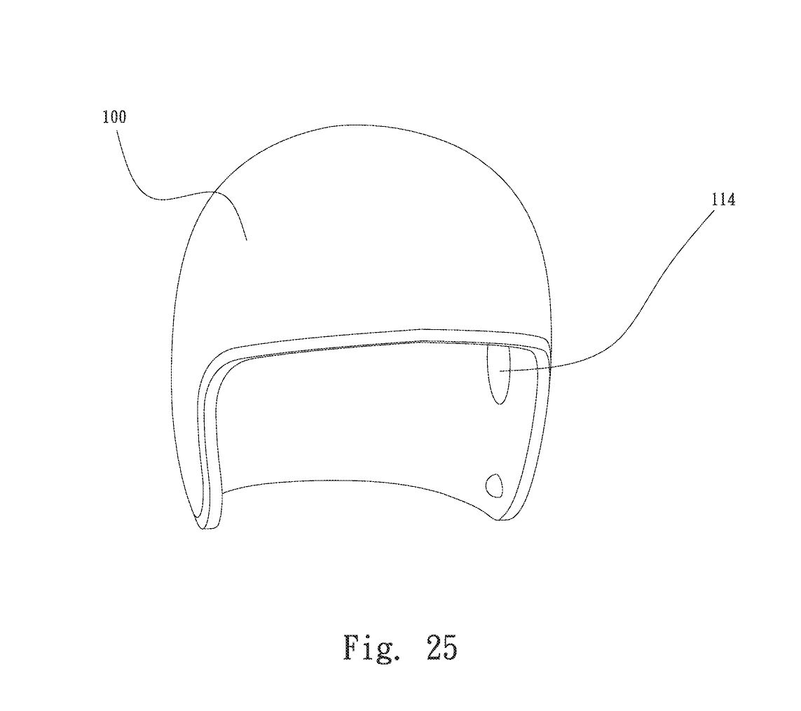

In general, if the user wears the helmet body 100 in a non-upright state as shown in FIG. 25, the control unto 112 will receive the angular velocity information continuously during the movement of the helmet body 100 and generates the dynamic information that recognizes the helmet body 100 is in a turning state to further provide the incorrect refined geographical location information to the user.

However, by means of the compensation of the current step in which when the control unit 112 determines the helmet body 100 moves in a linear manner through step S602, the control unit 112 recognizes the helmet body 100 is in the turning state based on the piece of dynamic information generated through step S605 (e.g., the turning state at each time moment is a fixed gesture when the helmet body 100 moves in a liner manner). For example, the piece of dynamic information which is fixed at each time moment when the helmet body 100 moves in a linear manner is multiplied by a weighted value a (i.e., the offset) or three components of the piece of dynamic information containing three-axis dynamic information are multiplied by weighted values β, γ, and δ (i.e., the offsets), respectively. Therefore, the user can obtain a more precise refined geographical location information through the piece of compensated dynamic information. The current step is not limited to use the above compensation method. In a practical embodiment, other equivalent compensation methods can be used to obtain the effect of the current step.

Therefore, by means of the design of the present invention, the user wearing the helmet body 100 can use the gyroscope 104, the positioning unit 106, and the electronic compass 108 disposed on the helmet body 100 to sense the dynamic characteristics of the helmet body 100 and then mark them on the electronic map to generate the refined geographical location information which is then outputted to inform the user through the output unit 114. Also, additional uses of the accelerometer 122 and the compensation step will obtain a more precise refined geographical location information and increase the resolution of the identified current geographical location of the user. Moreover, through the uses of the photographing unit 120 and the image recognition step, the user wearing the helmet body 100 can recognize his/her facing direction and position relative to neighboring landscapes, which effectively decreases the possibility of an accident when the user is identifying his/her current location.

The above-mentioned embodiments are only the preferred ones of the present invention. All variations regarding the above method, shape, structure, and device according to the claimed scope of the present invention should be embraced by the scope of the appended claims of the present invention.

What is claimed is:

1. An apparatus for refining a geographical location based on dynamic characteristics of a helmet, comprising:
a helmet body;
a storage unit disposed on the helmet body and storing a piece of basic angular velocity information, wherein the storage unit has an electronic map module for providing an electronic map which has a plurality of pieces of landscape and geographical information;
a gyroscope disposed on the helmet body for generating a piece of angular velocity information;
a positioning unit disposed on the helmet body for generating a piece of location information;
an electronic compass disposed on the helmet body for generating a piece of magnetic flux information; and
a control unit disposed on the helmet body and connected to the storage unit, the gyroscope, the positioning unit, and the electronic compass, wherein the control unit receives the piece of angular velocity information, the piece of location information, and the piece of magnetic flux information, wherein the control unit compares the received piece of angular velocity information with the piece of basic angular velocity information in the storage unit to generate a piece of dynamic information, wherein the control unit marks the piece of dynamic information, the piece of location information, and the piece of magnetic flux information on the electronic map to generate a piece of refined geographical location information sent to an output unit.

2. The apparatus for refining a geographical location based on dynamic characteristics of a helmet according to claim 1, wherein the control unit has a dynamic information module and a location refining module, wherein the dynamic information module compares the received piece of angular velocity information with the piece of basic angular velocity information to generate the piece of dynamic information, wherein the location refining module marks the piece of dynamic information, the piece of location information, and the piece of magnetic flux information on the electronic map to generate the piece of refined geographical location information.

3. The apparatus for refining a geographical location based on dynamic characteristics of a helmet according to claim 1, wherein the output unit is selected to be one of a projector, a display, and a speaker.

4. The apparatus for refining a geographical location based on dynamic characteristics of a helmet according to claim 1, further comprising an input unit disposed on the helmet body and connected to the control unit for generating a command signal sent to the control unit, wherein the control unit controls the gyroscope, the positioning unit, and the electronic compass based on the command signal to generate the piece of angular velocity information, the piece of location information, and the piece of magnetic flux information, respectively.

5. The apparatus for refining a geographical location based on dynamic characteristics of a helmet according to claim 1, further comprising a photographing unit disposed on the helmet body and connected to the control unit, wherein the photographing unit is used to generate a piece of image information sent to the control unit, wherein the storage unit further comprises an indicator image information module for providing at least one indicator image feature and an indicator description corresponding to the indicator image feature, wherein the control unit receives the piece of image information, wherein the control unit further comprises an image recognition module which searches the indicator image information module for the indicator image feature identical to the piece of image information and sends the indicator description corresponding to the indicator image feature to the output unit.

6. The apparatus for refining a geographical location based on dynamic characteristics of a helmet according to claim 5, wherein the indicator image feature of the indicator image information module corresponds to one of the pieces of landscape and geographical information of the electronic map, wherein the control unit further comprises a locating module which receives the piece of the location information and searches for the pieces of landscape and geographical information within a preset distance from the helmet body, wherein the image recognition module searches the indicator image information module based on the pieces of landscape and geographical information for the indicator image feature identical to the piece of image information.

7. The apparatus for refining a geographical location based on dynamic characteristics of a helmet according to claim 1, further comprising an accelerometer disposed on the helmet body and connected to the control unit for generating a piece of acceleration information sent to the control unit, wherein the control unit further comprises a determination module which determines the helmet body moves in a linear manner or a non-linear manner based on the piece of acceleration information, the piece of location information, and the piece of magnetic flux information, wherein the determination module determines the helmet body is in an upright state or a turning state based on the piece of dynamic information, wherein the control unit further comprises a compensation module for providing an offset to compensate the piece of dynamic information.

8. A system for refining a geographical location based on dynamic characteristics of a helmet, comprising:
a server having an electronic map module for providing an electronic map which has a plurality of pieces of landscape and geographical information;
a helmet body;
a storage unit disposed on the helmet body and storing a piece of basic angular velocity information;
a gyroscope disposed on the helmet body for generating a piece of angular velocity information;
a positioning unit disposed on the helmet body for generating a piece of location information;
an electronic compass disposed on the helmet body for generating a piece of magnetic flux information;
a communication unit disposed on the helmet body for connecting to the server directly or indirectly; and
a control unit disposed on the helmet body and connected to the storage unit, the gyroscope, the positioning unit, and the electronic compass, wherein the control unit receives the piece of angular velocity information, the piece of location information, and the piece of magnetic flux information, wherein the control unit compares the received angular velocity information with the basic angular velocity information in the storage unit to generate a piece of dynamic information, wherein the control unit downloads the electronic map from the server through the communication unit and marks the piece of dynamic information, the piece of location information, and the piece of magnetic flux information on the electronic map to generate a piece of refined geographical location information sent to an output unit.

9. The system for refining a geographical location based on dynamic characteristics of a helmet according to claim 8, wherein the control unit has a dynamic information module and a location refining module, wherein the dynamic information module compares the received piece of angular velocity information with the piece of basic angular velocity information to generate the piece of dynamic information, wherein the location refining module marks the piece of dynamic information, the piece of location information, and the piece of magnetic flux information on the electronic map to generate the piece of refined geographical location information.

10. The system for refining a geographical location based on dynamic characteristics of a helmet according to claim 8, wherein the output unit is selected to be one of a projector, a display, and a speaker.

11. The system for refining a geographical location based on dynamic characteristics of a helmet according to claim 8, further comprising an input unit disposed on the helmet body and connected to the control unit for generating a command signal sent to the control unit, wherein the control unit controls the gyroscope, the positioning unit, and the electronic compass based on the command signal to generate the piece of angular velocity information, the piece of location information, and the piece of magnetic flux information, respectively.

12. The system for refining a geographical location based on dynamic characteristics of a helmet according to claim 8, further comprising a photographing unit disposed on the helmet body and connected to the control unit for generating a piece of image information sent to the control unit, wherein the storage unit further comprises an indicator image information module for providing at least one indicator image feature and an indicator description corresponding to the indicator image feature, wherein the control unit receives the piece of image information, wherein the control unit further comprises an image recognition module which searches the indicator image information module for the indicator image feature identical to the piece of image information and sends the indicator description corresponding to the indicator image feature to the output unit.

13. The system for refining a geographical location based on dynamic characteristics of a helmet according to claim 12, wherein the indicator image feature of the indicator image information module corresponds to one of the pieces of landscape and geographical information of the electronic map, wherein the control unit further comprises a locating module which receives the piece of the location information and searches for the pieces of landscape and geographical information within a preset distance from the helmet body, wherein the image recognition module searches the indicator image information module based on the pieces of landscape and geographical information for the indicator image feature identical to the piece of image information.

14. The system for refining a geographical location based on dynamic characteristics of a helmet according to claim 8, further comprising an accelerometer disposed on the helmet body and connected to the control unit for generating a piece of acceleration information sent to the control unit, wherein the control unit further comprises a determination module which determines the helmet body moves in a linear manner or a non-linear manner based on the piece of acceleration information, the piece of location information, and the piece of magnetic flux information, wherein the determination module determines the helmet body is in an upright state or a turning state based on the piece of dynamic information, wherein the control unit further comprises a compensation module for providing an offset to compensate the piece of dynamic information.

15. A method for refining a geographical location based on dynamic characteristics of a helmet, which is applied to a helmet body, the method comprising the steps of:
receiving a piece of angular velocity information, a piece of location information, and a piece of magnetic flux information generated by a gyroscope, a positioning unit, and an electronic compass, respectively, through a control unit disposed on the helmet body;
comparing the received piece of angular velocity information with a piece of basic angular velocity information in a storage unit through the control unit to generate a piece of dynamic information;
marking the piece of dynamic information, the piece of location information, and the piece of magnetic flux information on an electronic map through the control unit to generate a piece of refined geographical location information, wherein the electronic map has a plurality of pieces of landscape and geographical information; and
sending the piece of refined geographical location information by the control unit to an output unit.

16. The method for refining a geographical location based on dynamic characteristics of a helmet according to claim 15, wherein the control unit has a dynamic information module and a location refining module, wherein the dynamic information module compares the received piece of angular velocity information with the piece of basic angular velocity information to generate the piece of dynamic information, wherein the location refining module marks the piece of dynamic information, the piece of location information, and the piece of magnetic flux information on the electronic map to generate the piece of refined geographical location information.

17. The method for refining a geographical location based on dynamic characteristics of a helmet according to claim 15, further comprising the step of controlling the gyroscope, the positioning unit, and the electronic compass through the control unit based on a command signal generated by an input unit to generate the piece of angular velocity information, the piece of location information, and the piece of magnetic flux information, respectively, before the step of receiving the piece of angular velocity information, the piece of location information, and the piece of magnetic flux information generated by the gyroscope, the positioning unit, and the electronic compass, respectively, through the control unit disposed on the helmet body.

18. The method for refining a geographical location based on dynamic characteristics of a helmet according to claim 15, wherein the storage unit further comprises an indicator image information module for providing at least one indicator image feature and an indicator description corresponding to the indicator image feature.

19. The method for refining a geographical location based on dynamic characteristics of a helmet according to claim 18, further comprising the step of recognizing images which comprises the steps of:
receiving a piece of image information generated by a photographing unit through the control unit;
searching the indicator image information module by the control unit through an image recognition module for the indicator image feature identical to the piece of image information; and
sending the indicator description identical to the indicator image feature of the piece of image information by the control unit to the output unit to be outputted.

20. The method for refining a geographical location based on dynamic characteristics of a helmet according to claim 19, further comprising the step of searching for the pieces of landscape and geographical information within a preset distance from the helmet body by the control unit based on the piece of location information through a locating module, wherein the indicator image feature corresponds to one of the pieces of landscape and geographical information, before the step of searching the indicator image information module by the control unit through the image recognition module for the indicator image feature identical to the piece of image information.

21. The method for refining a geographical location based on dynamic characteristics of a helmet according to claim 15, wherein the step of receiving the piece of angular velocity information, the piece of location information, and the piece of magnetic flux information generated by the gyroscope, the positioning unit, and the electronic compass, respectively, through the control unit disposed on the helmet body further comprises the step of receiving a piece of acceleration information generated by an accelerometer through the control unit.

22. The method for refining a geographical location based on dynamic characteristics of a helmet according to claim 21, wherein the step of comparing the received piece of angular velocity information with the piece of basic angular velocity information in the storage unit through the control unit to generate the piece of dynamic information further comprises the steps of:
determining the helmet body moves in a linear manner or a non-linear manner based on the piece of acceleration information, the piece of location information, and the piece of magnetic flux information by a determination module of the control unit;
determining the helmet body is in an upright state or a turning state based on the piece of dynamic information by the determination module of the control unit; and
providing an offset through a compensation module by the control unit to compensate the piece of dynamic information when the determination module of the control unit determines the helmet body moves in the linear manner and in the turning state.
